(19) United States
(12) Patent Application Publication
(10) Pub. No.: US 2026/0248021 A1
(43) Pub. Date: Aug. 20, 2026

(54) SEMICONDUCTOR DEVICE

(71) Applicant: SHINKO ELECTRIC INDUSTRIES CO., LTD., Nagano-shi (JP)

(72) Inventor: Masahiro Miyajima, Nagano-shi (JP)

(73) Assignee: SHINKO ELECTRIC INDUSTRIES CO., LTD., Nagano-shi (JP)

(21) Appl. No.: 19/539,864

(22) Filed: Feb. 13, 2026

(30) Foreign Application Priority Data
Feb. 18, 2025 (JP) 2025-024193

(51) Int. Cl. H10W 74/01; H10W 74/10; H10W 74/15; H10W 90/00

(52) U.S. Cl. CPC H10W 74/012; H10W 74/117; H10W 74/15; H10W 90/724

(57) ABSTRACT

A semiconductor device includes a wiring substrate including a connection pad, two electronic components mounted on the wiring substrate, and a connection substrate extending over the electronic components and mounted on the electronic components to electrically connect the electronic components. The electronic components each include a main body, a first electrode pad electrically connected to the connection pad, a second electrode pad opposite to the first electrode pad, and a through electrode extending through the main body and electrically connecting the first and second electrode pads. The connection substrate includes a structural body including a first insulation layer, and a wiring structural body stacked on the structural body and having a structure in which first wiring layers and second insulation layers are stacked. The first insulation layer is thicker than each second insulation layer. The lowermost one of the first wiring layers is electrically connected to the second electrode pad.

### CROSS-REFERENCE TO RELATED APPLICATIONS

This application is based upon and claims the benefit of priority from Japanese Patent Application No. 2025-024193, filed on Feb. 18, 2025, the entire contents of which are incorporated herein by reference.

### BACKGROUND

### 1. Field The following description relates to a semiconductor device.

### 2. Description of Related Art

JP2022-177703A discloses a semiconductor device in which an interposer is mounted on a wiring substrate and multiple semiconductor chips are mounted on the interposer.

### SUMMARY

The yield of the semiconductor device needs to be improved.

In one general aspect, a semiconductor device includes a wiring substrate including a connection pad, two first electronic components mounted on an upper surface of the wiring substrate, and a connection substrate extending over the two first electronic components and mounted on upper surfaces of the two first electronic components. The connection substrate electrically connects the two first electronic components to each other. Each of the two first electronic components includes a main body, a first electrode pad arranged on a lower surface of the main body and electrically connected to the connection pad, a second electrode pad arranged on an upper surface of the main body, which is opposite from the first electrode pad, and a through electrode extending through the main body in a thickness direction and electrically connecting the first electrode pad and the second electrode pad. The connection substrate includes a first structural body including a first insulation layer, and a first wiring structural body stacked on a lower surface of the first structural body. The first wiring structural body has a structure in which multiple first wiring layers and multiple second insulation layers are stacked. The first insulation layer is greater in thickness than each of the second insulation layers. A lowermost first wiring layer of the first wiring layers is electrically connected to the second electrode pad.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a cross-sectional view of a semiconductor device in accordance with a first embodiment.

FIG. 2 is a partially enlarged cross-sectional view of the semiconductor device illustrated in FIG. 1.

FIG. 3 is a plan view of the semiconductor device illustrated in FIG. 2.

FIGS. 4, 5, 6, 7, 8, 9, 10, 11, 12, 13, 14, 15, and 16 are cross-sectional views illustrating a method for manufacturing a connection substrate in the first embodiment.

FIGS. 17 and 18 are cross-sectional views illustrating a method for manufacturing the semiconductor device of the first embodiment.

FIG. 19 is a plan view of a semiconductor device in accordance with a modified example.

FIG. 20 is a cross-sectional view of a semiconductor device in accordance with a second embodiment.

FIG. 21 is a cross-sectional view of a connection substrate in accordance with the second embodiment.

FIGS. 22, 23, 24, 25, 26, 27, and 28 are cross-sectional views illustrating a method for manufacturing the connection substrate of the second embodiment.

FIGS. 29 and 30 are cross-sectional views illustrating a method for manufacturing the semiconductor device of the second embodiment.

FIG. 31 is a cross-sectional view of a semiconductor device in accordance with a modified example.

FIG. 32 is a cross-sectional view of a semiconductor device in accordance with another modified example.

FIGS. 33 and 34 are cross-sectional views illustrating a method for manufacturing the semiconductor device illustrated in FIG. 32.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

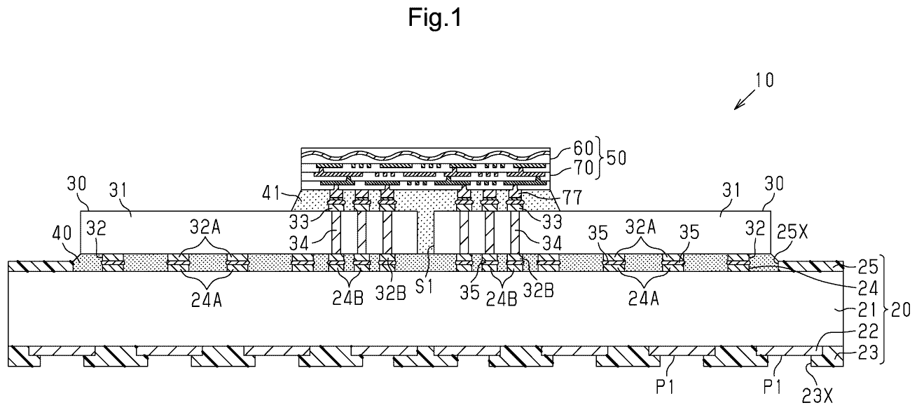

Embodiments will now be described with reference to the accompanying drawings. To facilitate understanding, hatching lines may not be illustrated or may be replaced by shadings in the cross-sectional drawings. In this specification, the term “plan view” refers to a view of a subject taken in a vertical direction as viewed in, for example, FIG. 1 (e.g., up-down direction in the drawing), unless otherwise specified. Also, the term “planar shape” refers to a shape of a subject taken in the vertical direction as viewed in, for example, FIG. 1, unless otherwise specified. Furthermore, in the present specification, “up-down direction” and “sideward direction” correspond to directions when the drawings are oriented to an appropriate position allowing reference numerals of the elements to be read correctly. In addition, in the description of the present disclosure, the numerical range of “X1 to X2” defined by an upper limit value X1 and a lower limit value X2 refers to being greater than or equal to X1 and less than or equal to X2, unless otherwise specified.

### First Embodiment

A first embodiment will now be described with reference to FIGS. 1 to 18.

### Structure of Semiconductor Device 10

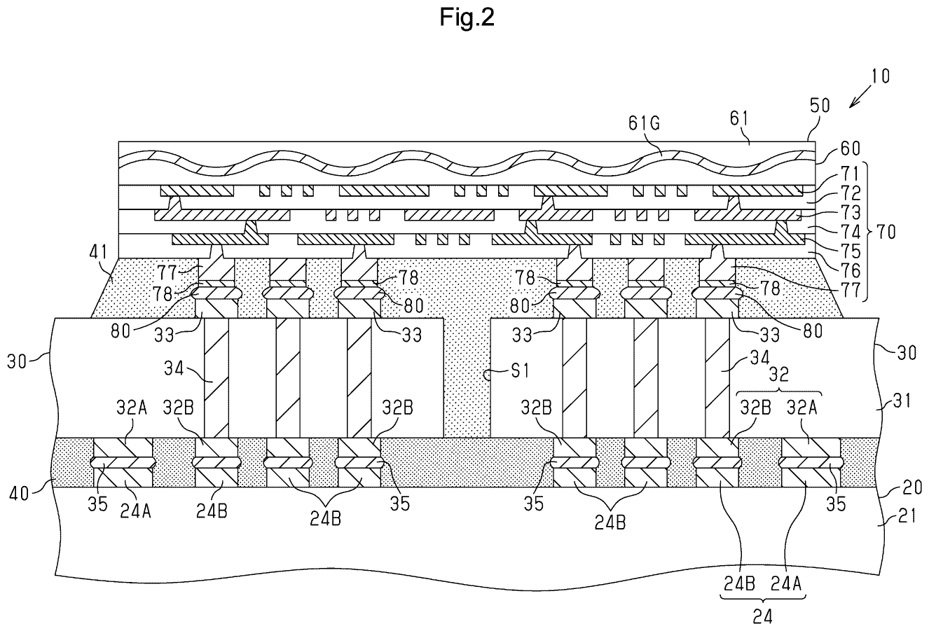

As illustrated in FIGS. 1 and 2, a semiconductor device 10 includes a wiring substrate 20, multiple semiconductor chips 30 mounted on the upper surface of the wiring substrate 20, underfill resins 40 and 41, and a connection substrate 50 mounted on the upper surface of the semiconductor chips 30. In the first embodiment, the semiconductor device 10 includes two semiconductor chips 30. The directions in each drawing do not necessarily indicate the orientation of the semiconductor device 10 when used.

### Structure of the Wiring Substrate 20

As illustrated in FIG. 1, the wiring substrate 20 includes, for example, a substrate body 21, a wiring layer 22, a solder resist layer 23, a wiring layer 24, and a solder resist layer 25. The material of the wiring layers 22 and 24 may be, for example, copper (Cu) or a copper alloy. The material of the solder resist layers 23 and 25 may be, for example, an insulating resin including a photosensitive resin such as a phenol resin or a polyimide resin as a main component. The solder resist layers 23 and 25 may include, for example, a filler such as silica or alumina.

The substrate body 21 may have, for example, a wiring structural body of alternately stacked insulative resin layers and wiring layers. In an example, the wiring structural body may, but does not necessarily have to, include a core substrate. The thickness of the substrate body 21 may be, for example, approximately 50 μm to 200 μm.

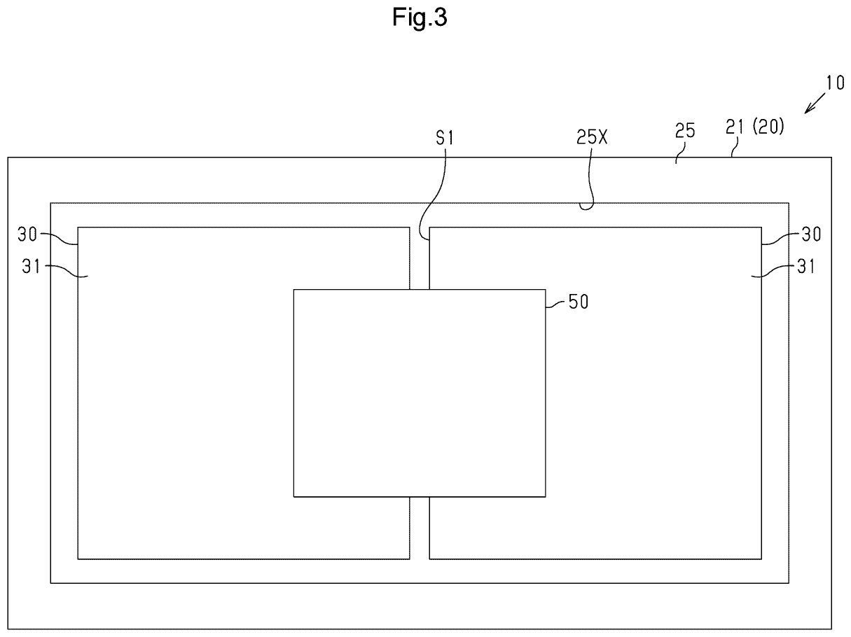

As illustrated in FIG. 3, for example, the planar shape of the substrate body 21 is rectangular. However, the planar shape of the substrate body 21 is not limited to a rectangle and may be any shape. The substrate body 21 is greater in planar size than the semiconductor chips 30. The planar size of the substrate body 21 may be, for example, approximately 20 mm×20 mm to 130 mm×130 mm. The underfill resins 40 and 41 are not illustrated in FIG. 3.

As illustrated in FIG. 1, the wiring layer 22 is formed on the lower surface of the substrate body 21. The wiring layer 22 is the lowermost wiring layer of the wiring substrate 20.

The solder resist layer 23 is formed on the lower surface of the substrate body 21 so as to cover the wiring layer 22. The solder resist layer 23 is the outermost (here, lowermost) insulation layer of the wiring substrate 20.

The solder resist layer 23 includes a plurality of openings 23X formed to expose parts of the lower surface of the wiring layer 22 as external connection pads P1. The external connection pads Pl are connected to external connection terminals used when the semiconductor device 10 is mounted on a mount substrate such as a motherboard.

A surface-processed layer may be formed on the lower surface of the wiring layer 22 exposed at the bottom of each opening 23X. Examples of the surface-processed layer include a gold (Au) layer, a nickel (Ni) layer/Au layer (metal layer in which Ni layer and Au layer are stacked in this order), a Ni layer/palladium (Pd) layer/Au layer (metal layer in which Ni layer, Pd layer, and Au layer are stacked in this order), or the like. Other examples of the surface-processed layer include a Ni layer/Pd layer (metal layer in which Ni layer and Pd layer are stacked in this order), and a Pd layer/Au layer (metal layer in which Pd layer and Au layer are stacked in this order). The Au layer is a metal layer of Au or a Au alloy. The Ni layer is a metal layer of Ni or a Ni alloy. The Pd layer is a metal layer of Pd or a Pd alloy. Each of the Au layer, the Ni layer, and the Pd layer may be, for example, a metal layer (electroless plated layer) formed through an electroless plating process or a metal layer (electrolytic plated layer) formed through an electrolytic plating process. Alternatively, the surface-processed layer may be an organic solderability preservative (OSP) film formed by performing an oxidation-resisting process, such as an OSP process, on the lower surface of the wiring layer 22 exposed from the openings 23X. The OSP film may be a coating of an organic compound such as an azole compound or an imidazole compound. When a surface-processed layer is formed on the lower surface of the wiring layer 22, the surface-processed layer is used as the external connection pads P1.

In the present example, the external connection terminals are arranged on the external connection pads P1. Alternatively, the wiring layer 22 exposed at the bottom of each opening 23X (or surface-processed layer formed on wiring layer 22, if any) may be used as external connection terminals.

The wiring layer 24 is formed on the upper surface of the substrate body 21. The wiring layer 24 is the uppermost wiring layer of the wiring substrate 20. The wiring layer 24 is electrically connected to the wiring layer 22 by, for example, the wiring layers and through electrodes in the substrate body 21. The wiring layer 24 is, for example, arranged in a mount region where the semiconductor chips 30 are mounted in accordance with arrangement of electrode pads 32 of the semiconductor chips 30. The wiring layer 24 is used as, for example, electronic component mounting pads for electrical connection with an electronic component, such as the semiconductor chips 30.

The wiring layer 24 includes, for example, multiple connection pads 24A and multiple connection pads 24B. The connection pads 24A are, for example, arranged in a peripheral part of the mount region on which the semiconductor chips 30 are mounted. The connection pads 24B are, for example, arranged in a central part of the mount region.

The solder resist layer 25 is formed on the upper surface of the substrate body 21 so as to expose the wiring layer 24. The solder resist layer 25 is formed so as to expose the connection pads 24A and 24B. The solder resist layer 25 is the outermost (here, uppermost) insulation layer of the wiring substrate 20. The solder resist layer 25 has an opening 25X extending through the solder resist layer 25 in the thickness direction and exposing a portion of the upper surface of the substrate body 21 and the wiring layer 24.

As illustrated in FIG. 3, for example, in plan view, the opening 25X overlaps the mount region on which the semiconductor chips 30 are mounted. In an example, in plan view, the opening 25X overlaps the entirety of the mount region. The solder resist layer 25, for example, surrounds the mount region in plan view. In an example, the solder resist layer 25 covers a peripheral region of the upper surface of the substrate body 21 along the entire perimeter. As illustrated in FIG. 1, the opening 25X exposes, for example, the wiring layer 24 located in the mount region and the upper surface of the substrate body 21 located in the mount region.

A surface-processed layer may be formed on the surface (upper and side surfaces or only upper surface) of the wiring layer 24 exposed from the solder resist layer 25. The surface-processed layer may be an OSP film or a metal layer, such as an Au layer, an Ni layer/Au layer, an Ni layer/Pd layer/Au layer, an Ni layer/Pd layer, or a Pd layer/Au layer.

Structure of the Semiconductor Chip 30 Each semiconductor chip 30 includes a main body 31, the electrode pads 32 arranged on a lower part of the semiconductor chip 30, multiple electrode pads 33 arranged on an upper part of the semiconductor chip 30, and multiple through electrodes 34.

The semiconductor chip 30 may be, for example, a logic chip such as a central processing unit (CPU) chip or a graphics processing unit (GPU) chip. Furthermore, the semiconductor chips 30 may each be, for example, a memory chip, such as a dynamic random access memory (DRAM) chip, a flash memory chip, or the like. When multiple semiconductor chips 30 are mounted on the wiring substrate 20, a logic chip may be mounted on the wiring substrate 20 in combination with a memory chip.

The main body 31 is, for example, box-shaped. The thickness of the main body 31 may be, for example, approximately 50 μm to 200 μm. The main body 31 is formed from, for example, silicon (Si) or silicon carbide (SiC). The main body 31 has a circuit formation surface (in the embodiment, lower surface) and a back surface (upper surface) located opposite from the circuit formation surface.

As illustrated in FIG. 3, for example, the planar shape of the main body 31 is rectangular. However, the planar shape of the main body 31 is not limited to a rectangle and may be any shape. The planar size of the main body 31 may be, for example, approximately 3 mm×3 mm to 30 mm×30 mm. The thickness of the main body 31 may be, for example, approximately 50 μm to 100 μm.

As illustrated in FIG. 1, the electrode pads 32, for example, project downward from the lower surface of the main body 31. The thickness of each electrode pad 32 may be, for example, approximately 2 μm to 20 μm. The electrode pads 32 may be embedded in the main body 31.

The electrode pads 32 include electrode pads 32A and electrode pads 32B. The electrode pads 32A are, for example, faced to the connection pads 24A. The electrode pads 32B are, for example, faced to the connection pads 24B.

The electrode pads 33 are arranged at a side opposite from the electrode pads 32. The electrode pads 33, for example, project upward from the upper surface of the main body 31. The electrode pads 33 are, for example, arranged to overlap the electrode pads 32B in plan view. The thickness of each electrode pad 33 may be, for example, approximately 2 μm to 20 μm. The electrode pads 33 may be embedded in the main body 31.

The through electrodes 34 extend through the main body 31 in the thickness direction. The through electrodes 34, for example, extend straight in the thickness direction of the main body 31. The through electrodes 34 electrically connect the electrode pads 33 and the electrode pads 32B to each other.

The material of the electrode pads 32 and 33 and the through electrodes 34 may be, for example, a metal such as aluminum (Al) or copper or an alloy including at least one selected from a group consisting of these metals.

The semiconductor chips 30 are mounted on the wiring substrate 20. Each semiconductor chip 30 is flip-chip-mounted on the wiring substrate 20 when the lower surface, that is, the circuit formation surface, of the main body 31 is faced to the upper surface of the wiring substrate 20 (i.e., in face-down state). In an example, the electrode pads 32 of the semiconductor chip 30 are electrically connected to the wiring layer 24 of the wiring substrate 20 by bonding members 35. The electrode pads 32A of the semiconductor chip 30 are electrically connected to the connection pads 24A of the wiring substrate 20 by the bonding members 35. The electrode pads 32B of the semiconductor chip 30 are electrically connected to the connection pads 24B of the wiring substrate 20 by the bonding members 35. Thus, the electrode pads 33 of the semiconductor chip 30 are electrically connected to the connection pads 24B by the through electrodes 34, the electrode pads 32B, and the bonding members 35.

The bonding members 35 may be, for example, a solder layer. The material of the solder layer may be, for example, Pb-free solder of Sn—Ag, Sn—Cu, or Sn—Ag—Cu.

The two semiconductor chips 30 are spaced apart by a given first gap S1 and arranged next to each other in the sideward direction of the drawing. In other words, the first gap S1 is located between the two semiconductor chips 30. In each semiconductor chip 30, the electrode pads 32B and the electrode pads 33 are, for example, arranged in the vicinity of the first gap S1. The connection pads 24B of the wiring substrate 20 are, for example, arranged in the vicinity of the first gap S1.

### Structure of the Underfill Resin 40

The underfill resin 40 fills a gap between the wiring substrate 20 and the semiconductor chip 30. The underfill resin 40 fills a gap between the upper surface of the substrate body 21 exposed from the opening 25X and the lower surface of the main body 31. The underfill resin 40 encapsulates the wiring layer 24, the electrode pads 32, and the bonding members 35. The underfill resin 40 fills, for example, the opening 25X in the solder resist layer 25. The material of the underfill resin 40 may be, for example, an insulating resin such as epoxy resin.

### Structure of the Connection Substrate 50

The connection substrate 50 electrically connects the two semiconductor chips 30. The connection substrate 50 extends over the two semiconductor chips 30 and are mounted on the upper surfaces of the semiconductor chips 30. The connection substrate 50 extends over the first gap SI located between the two semiconductor chips 30 and is mounted on the upper surfaces of the semiconductor chips 30.

The connection substrate 50 may have any planar shape and any planar size. As illustrated in FIG. 3, in the first embodiment, the planar shape of the connection substrate 50 is rectangular. The planar size of the connection substrate 50 is smaller than the planar size of the two semiconductor chips 30 combined. The planar size of the connection substrate 50 is smaller than the planar size of a single semiconductor chip 30. The planar size of the semiconductor chip 30 may be, for example, approximately 3 mm×3 mm to 30 mm×30 mm.

As illustrated in FIG. 2, the connection substrate 50 includes, for example, a first structural body 60 and a first wiring structural body 70 stacked on the lower surface of the first structural body 60. In the first embodiment, the first structural body 60 includes only an insulation layer 61. In the first embodiment, the first wiring structural body 70 includes a wiring layer 71, an insulation layer 72, a wiring layer 73, an insulation layer 74, a wiring layer 75, an insulation layer 76, and a wiring layer 77.

Structure of the Insulation Layer 61 The insulation layer 61 is greater in thickness than each of the insulation layers 72, 74, and 76 of the first wiring structural body 70. The insulation layer 61 is greater in rigidity than the insulation layers 72, 74, and 76. The thickness of the insulation layer 61 may be, for example, approximately 30 μm to 80 μm.

The insulation layer 61 includes a non-photosensitive resin as a main component. The main component of the insulation layer 61 may be, for example, a thermosetting non-photosensitive resin, such as an epoxy resin, an imide resin, a phenol resin, a cyanate resin, or the like. The insulation layer 61, for example, includes a thermosetting non-photosensitive resin as the main component and includes a reinforcement member 61G. The insulation layer 61 may be formed by impregnating the reinforcement member 61G with a thermosetting non-photosensitive resin. The reinforcement member 61G may be, for example, a woven or non-woven fabric formed of a glass fiber, a carbon fiber, an aramid fiber, or the like.

### Structure of the First Wiring Structural Body 70

The wiring layers 71, 73, 75, and 77 of the first wiring structural body 70 are fine wiring. The material of the wiring layers 71, 73, 75, and 77 may be, for example, copper or a copper alloy. The thickness of each of the wiring layers 71, 73, and 75 may be, for example, approximately 1 μm to 3 μm. The thickness of the wiring layer 77 may be, for example, approximately 5 μm to 15 μm. The line/space (L/S) of the wiring layers 71, 73, 75, and 77 may be, for example, approximately 1 μm/1 μm to 3 μm/3 μm. In the term “line/space”, line represents the line width, and space represents the distance between adjacent wirings (interline distance). In an example, when the line/space is 1 μm/1 μm to 3 um/3 μm, the line width is greater than or equal to 1 μm and less than or equal to 3 μm, and the interline distance between adjacent lines is greater than or equal to 1 μm and less than or equal to 3 μm. The line width does not necessarily have to be equal to the interline distance.

The insulation layers 72, 74, and 76 of the first wiring structural body 70 each include, for example, a photosensitive resin as a main component. The material of the insulation layers 72, 74, and 76 may be, for example, a photosensitive insulating resin including a phenol resin, a polyimide resin, or the like, as a main component. The insulation layers 72, 74, and 76 may include, for example, fillers such as silica or alumina. Each of the insulation layers 72, 74, and 76 is smaller in thickness than the insulation layer 61. The thickness of each of the insulation layers 72, 74, and 76 may be, for example, approximately 5 μm to 10 μm.

The wiring layer 71 is formed on the lower surface of the insulation layer 61. The insulation layer 72 is formed on the lower surface of the insulation layer 61 and covers the wiring layer 71. The wiring layer 73 is formed on the lower surface of the insulation layer 72. The wiring layer 73 is electrically connected to the wiring layer 71 by via wiring that extends through the insulation layer 72 in the thickness direction. The insulation layer 74 is formed on the lower surface of the insulation layer 72 and covers the wiring layer 73. The wiring layer 75 is formed on the lower surface of the insulation layer 74. The wiring layer 75 is electrically connected to the wiring layer 73 by via wiring that extends through the insulation layer 74 in the thickness direction. The insulation layer 76 is formed on the lower surface of the insulation layer 74 and covers the wiring layer 75.

The wiring layer 77 is formed on the lower surface of the insulation layer 76. The wiring layer 77 is formed in the lowermost layer of the connection substrate 50. The wiring layer 77 is electrically connected to the wiring layer 75 by via wiring that extends through the insulation layer 76 in the thickness direction. The wiring layer 77 projects downward from the lower surface of the insulation layer 76. The wiring layer 77 serves as electronic component mounting pads for electrical connection with an electronic component, such as the semiconductor chips 30.

The wiring layer 77 may have any planar shape and any planar size. The planar shape of the wiring layer 77 may be, for example, circular and have a diameter of approximately 20 μm to 30 μm. The pitch of the wiring layer 77 may be, for example, approximately 40 μm to 60 μm.

A surface-processed layer 78 may be formed on the surface (lower surface and side surface or only lower surface) of the wiring layer 77. In the first embodiment, the surface-processed layer 78 covers only the lower surface of the wiring layer 77. The surface-processed layer 78 may be, for example, an OSP film or a metal layer, such as a Au layer, a Ni layer/Au layer, a Ni layer/Pd layer/Au layer, a Ni layer/Pd layer, or a Pd layer/Au layer. When the surface-processed layer 78 is formed on the surface of the wiring layer 77, the surface-processed layer 78 serves as pads for mounting electronic components.

The connection substrate 50 is mounted on the upper surfaces of the two semiconductor chips 30 so that the wiring layer 77 is electrically connected to the electrode pads 33 of the semiconductor chips 30. The wiring layer 77 is electrically connected to the electrode pads 33 of the semiconductor chips 30 by the surface-processed layer 78 and bonding members 80. The portion of the wiring layer 77 electrically connected to the electrode pads 33 of one of the semiconductor chips 30 is electrically connected to the portion of the wiring layer 77 electrically connected to the electrode pads 33 of the other semiconductor chip 30 by the wiring layer 71, 73, and 75 of the first wiring structural body 70. Thus, the two semiconductor chips 30 are electrically connected to each other through the connection substrate 50. In other words, the connection substrate 50 includes the wiring layers 71, 73, 75, and 77 serving as wiring portions configured to electrically connect the two semiconductor chips 30.

The bonding members 80 may be, for example, a solder layer. The material of the solder layer may be, for example, Pb-free solder of Sn—Ag, Sn—Cu, or Sn—Ag—Cu.

### Structure of the Underfill Resin 41

The underfill resin 41 fills a gap between each semiconductor chip 30 and the connection substrate 50. The underfill resin 41 fills the gap between the upper surface of the main body 31 of the semiconductor chip 30 and the lower surface of the insulation layer 76 of the connection substrate 50. The underfill resin 41 encapsulates the electrode pads 33, the wiring layer 77, the surface-processed layer 78, and the bonding members 80. The underfill resin 41 fills, for example, the first gap S1 between the two semiconductor chips 30. The material of the underfill resin 41 may be, for example, an insulating resin such as epoxy resin.

### Method for Manufacturing the Connection Substrate 50

A method for manufacturing the connection substrate 50 will now be described. A method for collectively fabricating portions corresponding to connection substrates 50 and then singulating the connection substrates 50 will be described below. To facilitate understanding, parts that ultimately become elements of the connection substrate 50 are indicated by reference characters used to denote the final elements.

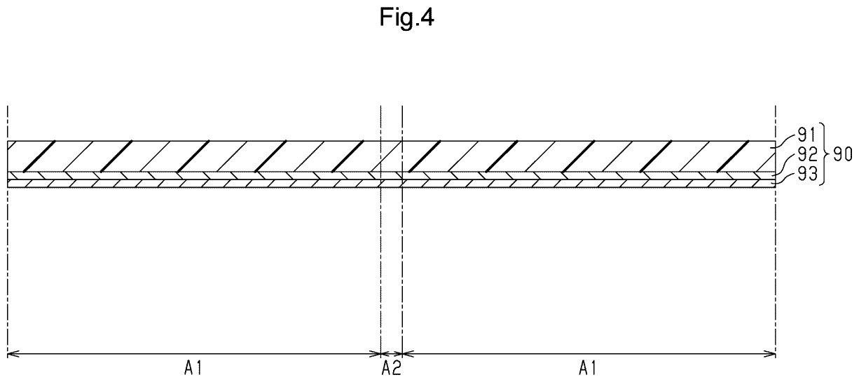

In the process illustrated in FIG. 4, a large support 90 is prepared. In an example, the support 90 includes multiple separate regions A1. The connection substrate 50 is formed in each separate region Al. The separate region Al refers to a region that is ultimately cut and singulated along a cutting region A2. The separate region Al will ultimately become a separate connection substrate 50. The number of separate regions Al in the support 90 is not limited. In the present embodiment, two separate regions Al are illustrated and will be described.

The support 90 has, for example, a structure in which a metal foil 92 and a metal film 93 are sequentially stacked on the lower surface of a base 91. The base 91 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. The metal foil 92 is, for example, a copper foil. The metal film 93 is, for example, formed on the lower surface of the metal foil 92 with a release layer located in between so that the metal film 93 is separable. The metal film 93 is, for example, a copper film. The release layer located between the metal foil 92 and the metal film 93 may be, for example, a metal oxide film or an organic layer. The material of the metal foil 92 is not limited to copper and may be a metal other than copper. The material of the metal film 93 is not limited to copper and may be a metal other than copper.

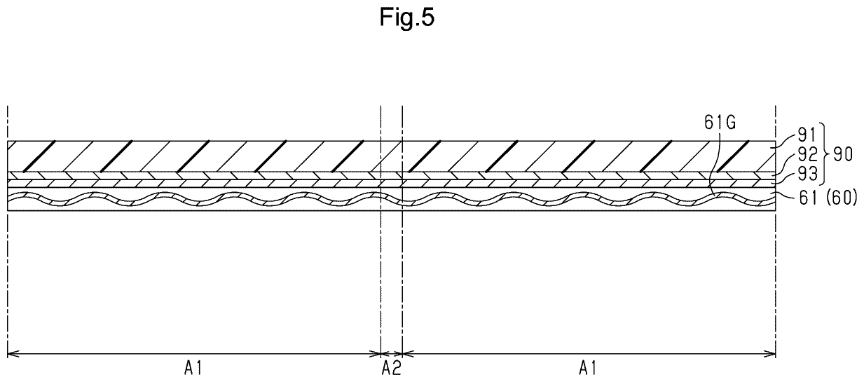

In the step illustrated in FIG. 5, the insulation layer 61 including the reinforcement member 61G is formed on the lower surface of the metal film 93. In an example, when a resin film is used as the insulation layer 61, the lower surface of the metal film 93 is laminated with the resin film. Then, the resin film is heated at a curing temperature or higher (e.g., approximately 130° C. to 200° C.) while being pressed so that the resin film is cured to form the insulation layer 61. The resin film may be, for example, a film of a thermosetting resin including an epoxy resin as a main component.

The lower surface of the insulation layer 61 may be polished. The polishing of the lower surface of the insulation layer 61 smooths the lower surface of the insulation layer 61. For example, a roughness value Ra of the lower surface of the insulation layer 61 before the polishing may be approximately 300 nm to 400 nm, and a roughness value Ra of the lower surface of the insulation layer 61 after the polishing may be approximately 15 nm to 40 nm. As a result of the polishing in the present step, the lower surface of the insulation layer 61 includes a polished surface. The lower surface of the insulation layer 61 may be polished by, for example, chemical mechanical polishing (CMP).

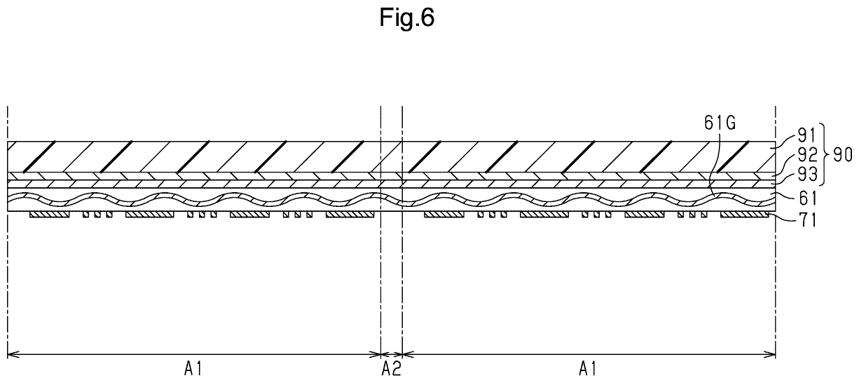

In the step illustrated in FIG. 6, the wiring layer 71 is formed on the lower surface of the insulation layer 61. The wiring layer 71 may be formed, for example, through any of various wiring formation processes such as a semi-additive process.

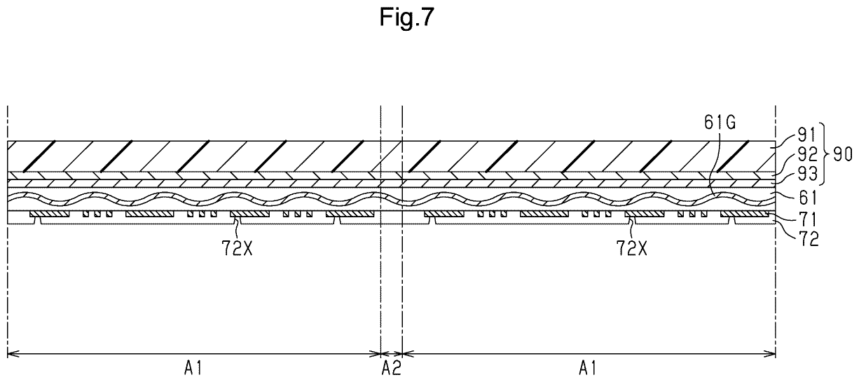

In the step illustrated in FIG. 7, the insulation layer 72 is formed on the lower surface of the insulation layer 61 and covers the wiring layer 71. Then, at given locations of the insulation layer 72, through holes 72X extend through the insulation layer 72 in the thickness direction and expose part of the lower surface of the wiring layer 71. When using a resin film as the insulation layer 72, for example, the lower surface of the insulation layer 61 is laminated with a resin film through thermocompression bonding, and then the resin film is patterned by photolithography to form the insulation layer 72.

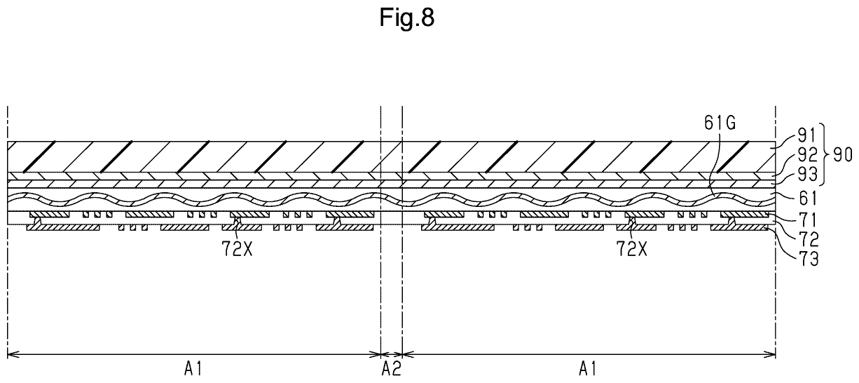

In the step illustrated in FIG. 8, the through holes 72X are filled with via wirings, and the wiring layer 73 is formed on the lower surface of the insulation layer 72 and is electrically connected to the wiring layer 71 by via wiring. The via wiring and the wiring layer 73 may be formed using various wiring forming processes, for example, a semi-additive process.

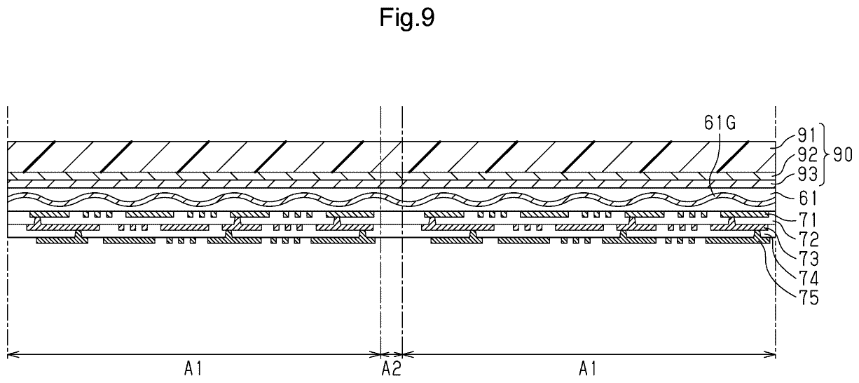

In the step illustrated in FIG. 9, the insulation layer 74 and the wiring layer 75 are sequentially formed on the lower surface of the insulation layer 72 in a manner similar to the steps of FIGS. 7 and 8.

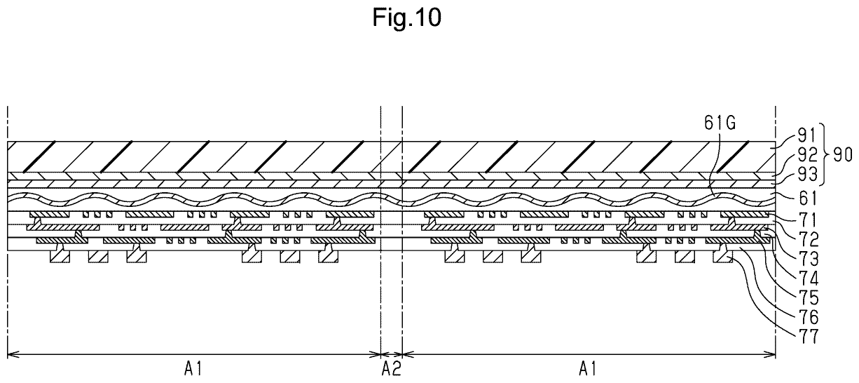

In the step illustrated in FIG. 10, the insulation layer 76 and the wiring layer 77 are sequentially formed on the lower surface of the insulation layer 74 in a manner similar to the steps of FIGS. 7 and 8.

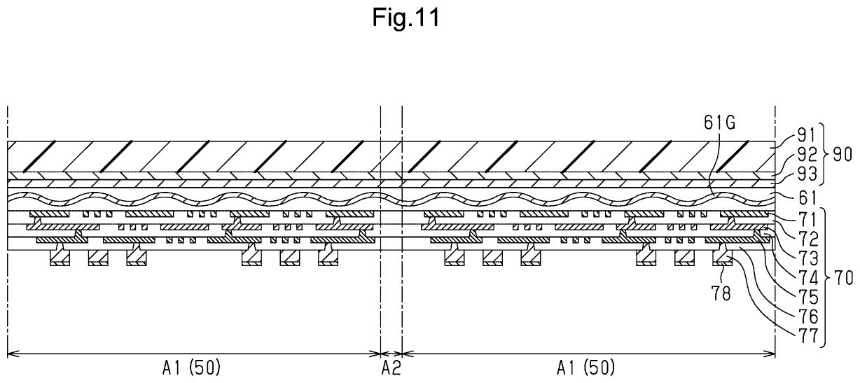

In the step illustrated in FIG. 11, the surface-processed layer 78 is formed on the lower surface of the wiring layer 77. The surface-processed layer 78 is formed through, for example, an electroless plating process.

The manufacturing steps described above form the first wiring structural body 70 on the lower surface of the insulation layer 61. Thus, a structure corresponding to the connection substrate 50 is manufactured on the separate region Al.

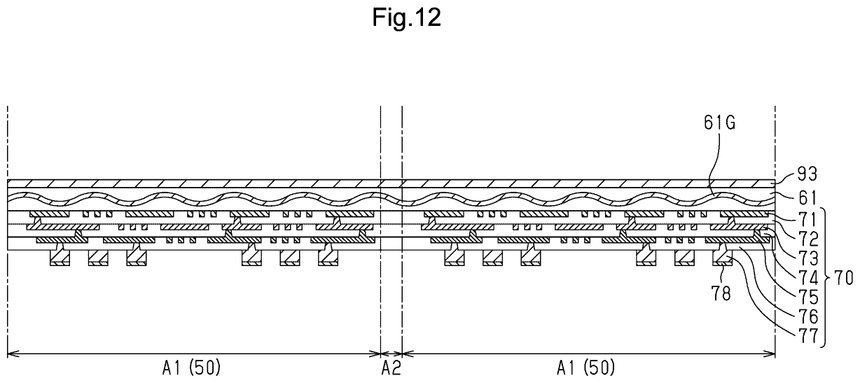

Then, the base 91 and the metal foil 92 are removed. In an example, the base 91 and the metal foil 92 are mechanically separated from the metal film 93. This exposes the upper surface of the metal film 93 to the outside as illustrated in FIG. 12.

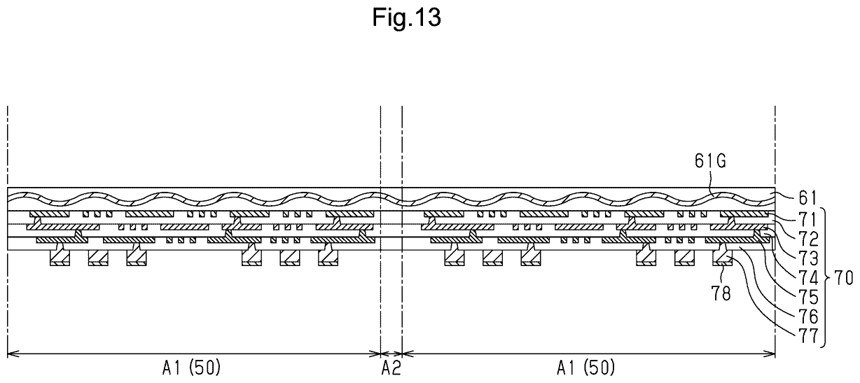

Then, the metal film 93 is removed. The metal film 93 is removed by, for example, etching. Although not illustrated, when the wiring layer 77 is covered by a protection member, the metal film 93 is etched and removed. This avoids etching of the wiring layer 77 during the etching of the metal film 93. In the present step, as illustrated in FIG. 13, the upper surface of the insulation layer 61 is exposed to the exterior.

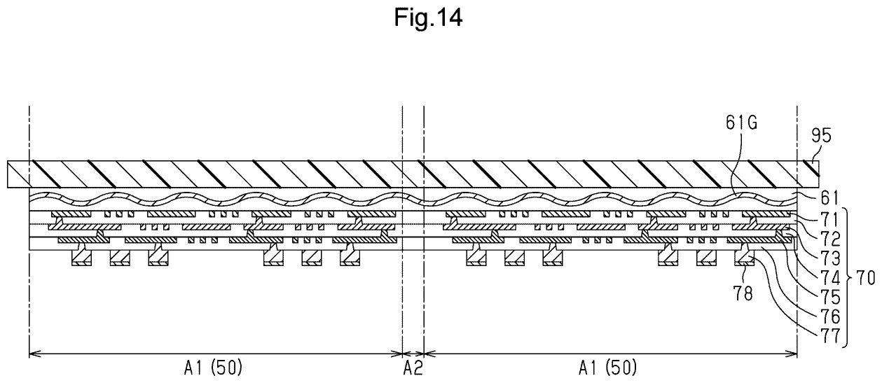

In the step illustrated in FIG. 14, tape 95 is adhered to the upper surface of the insulation layer 61. In an example, the tape 95 has a surface to which an adhesive (not illustrated) is applied. The surface of the tape 95 is attached to the upper surface of the insulation layer 61. In an example, the upper surface of the insulation layer 61 is laminated with a sheet of tape 95 through thermocompression bonding. The material of the tape 95 may be, for example, a polyimide resin or a polyester resin. The tape 95 may be, for example, an adhesive tape having an adhesive strength that decreases when irradiated with ultraviolet (UV).

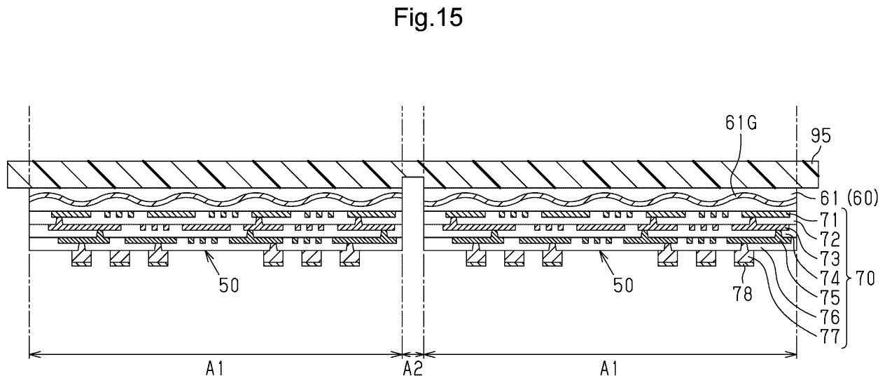

In the step illustrated in FIG. 15, the structural body to which the tape 95 is attached is cut using a dicing blade along the cutting region A2. In the present embodiment, the insulation layer 61 and the insulation layers 72, 74, and 76 of the first wiring structural body 70 located in the cutting region A2 are cut. This singulates the connection substrates 50, thereby manufacturing multiple connection substrates 50. In the present embodiment, in the cutting region A2, the tape 95 is cut partially in the thickness direction with a dicing blade or the like. Thus, the tape 95 remains undivided, and the multiple connection substrates 50 are adhered to the single tape 95.

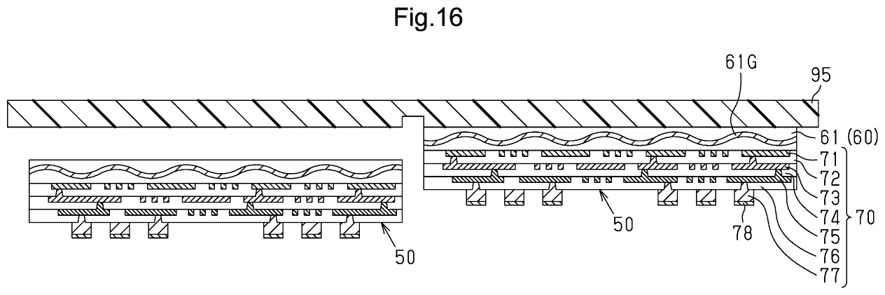

In the step illustrated in FIG. 16, the connection substrates 50 are mechanically separated from the tape 95. In an example, when the adhesive strength of the tape 95 decreases when irradiated with UV, the connection substrate 50 is readily separated from the tape 95 by the UV irradiation.

Manufacturing Method of the Semiconductor Device 10 A method for manufacturing the semiconductor device 10 will now be described. To facilitate understanding, parts that ultimately become elements of the semiconductor device 10 are indicated by reference characters used to denote the final elements.

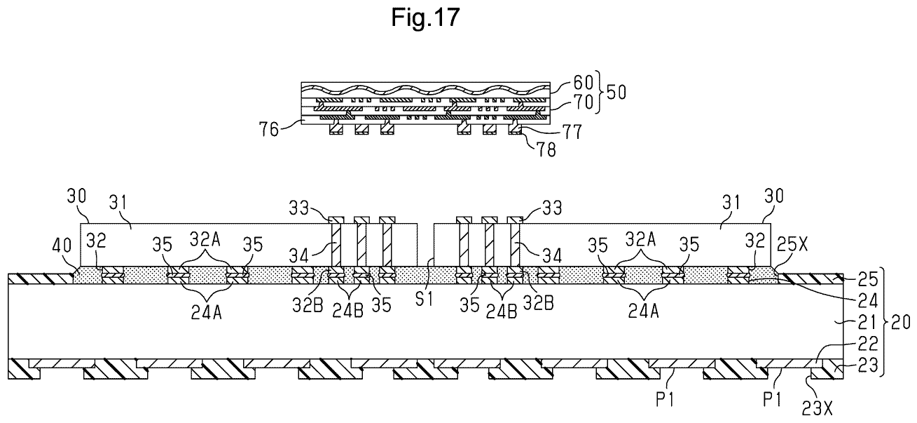

In the step illustrated in FIG. 17, the wiring substrate 20, including the substrate body 21, the wiring layers 22 and 24, and the solder resist layers 23 and 25, is manufactured. The wiring substrate 20 may be manufactured by a known manufacturing process. Thus, such a process will not be described in detail.

Multiple (in the first embodiment, two) semiconductor chips 30 are prepared. Each semiconductor chip 30 includes the main body 31, the electrode pads 32 and 33, and the through electrodes 34. The two semiconductor chips 30 are mounted on the wiring substrate 20. The two semiconductor chips 30 are arranged next to each other on the wiring substrate 20 and spaced apart by the given first gap S1 in the sideward direction of the drawing. Each semiconductor chip 30 is face down and is flip-chip-mounted on the wiring substrate 20. In an example, the electrode pads 32 of the semiconductor chip 30 are bonded to the wiring layer 24 of the wiring substrate 20 by the bonding members 35. In an example, when the bonding members 35 are formed of a solder layer, flux (not illustrated) is applied to the wiring layer 24, and then the wiring layer 24 is positioned relative to the electrode pads 32 while sandwiching the bonding members 35. Subsequently, a reflow process is performed at a temperature of approximately 230° C. to 260° C. This melts the bonding members 35, or the solder layer. The wiring layer 24 and the electrode pads 32 are electrically connected by the bonding members 35.

Then, the underfill resin 40 fills the gap between the wiring substrate 20 and the semiconductor chips 30, and the underfill resin 40 is cured. The underfill resin 40 may be, for example, applied to the lower surface of the main body 31 of the semiconductor chips 30 in advance. Then, when the semiconductor chips 30 are mounted, the underfill resin 40 may fill the gap to the upper surface of the substrate body 21.

In the step illustrated in FIG. 17, the connection substrate 50, manufactured by the steps illustrated in FIGS. 4 to 16, are prepared. The connection substrate 50 is arranged above the two semiconductor chips 30. In this step, the connection substrate 50 is arranged so that the insulation layer 76 and the wiring layer 77 are faced to the two semiconductor chips 30. In addition, the connection substrate 50 is arranged to extend over the two semiconductor chips 30. Further, the connection substrate 50 is positioned relative to the two semiconductor chips 30 so that the wiring layer 77 of the connection substrate 50 is vertically aligned with the electrode pads 33 of the semiconductor chips 30.

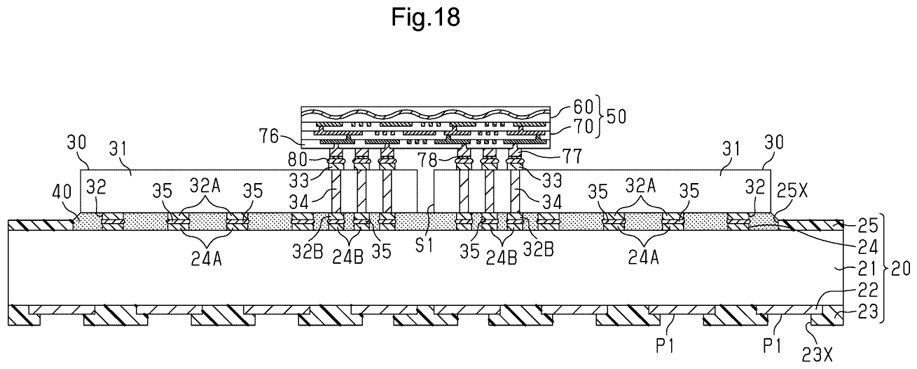

In the step illustrated in FIG. 18, the connection substrate 50 is mounted on the upper surfaces of the two semiconductor chips 30. In an example, the wiring layer 77 of the connection substrate 50 (the surface-processed layer 78 formed on the lower surface of the wiring layer 77) is bonded to the electrode pads 33 of the two semiconductor chips 30 by the bonding members 80. For example, when the bonding members 80 are formed of a solder layer, flux (not illustrated) is applied to the electrode pads 33, and then the electrode pads 33 are positioned relative to the wiring layer 77 while sandwiching the bonding members 80. Subsequently, a reflow process is performed at a temperature of approximately 230° C. to 260° C. This melts the bonding members 80, or the solder layer. The bonding members 80 electrically connect the electrode pads 33 and the wiring layer 77.

As illustrated in FIG. 1, the underfill resin 41 fills the gap between the semiconductor chips 30 and the connection substrate 50, and the underfill resin 41 is cured. In the first embodiment, the underfill resin 41 fills the first gap S1 between the two semiconductor chips 30. The semiconductor device 10 of the first embodiment is manufactured through the manufacturing steps described above.

In the first embodiment, the semiconductor chip 30 is an example of a first electronic component. The electrode pad 32 is an example of a first electrode pad. The electrode pad 33 is an example of a second electrode pad. The insulation layer 61 is an example of a first insulation layer. The wiring layers 71, 73, 75, and 77 are each an example of a first wiring layer. The insulation layers 72, 74, and 76 are each an example of a second insulation layer. The underfill resin 40 is an example of a second underfill resin. The underfill resin 41 is an example of a first underfill resin.

### Advantages of the First Embodiment

The first embodiment may have the advantages described below.

(1-1) In a typical semiconductor device, an interposer is mounted on a wiring substrate, and multiple semiconductor chips are mounted on the upper surface of the interposer. The interposer includes wiring portions configured to connect the semiconductor chips to each other and wiring portions configured to connect the semiconductor chips to the wiring substrate. This results in an increase in the area of the wiring portions of the interposer. The increase in the area of the wiring portions causes a decrease in the yield.

In this regard, in the semiconductor device 10 of the first embodiment, the two semiconductor chips 30 are mounted on the upper surface of the wiring substrate 20, and the connection substrate 50 is mounted on the upper surfaces of the two semiconductor chips 30. With this structure, the connection substrate 50 includes wiring portions configured to connect the two semiconductor chips 30 to each other. The connection substrate 50 does not need to include wiring portions configured to connect the two semiconductor chips 30 to the wiring substrate 20. Therefore, the area of the wiring portions of the connection substrate 50 is smaller than that of a typical interposer. This improves the yield of the connection substrate 50 and the yield of the semiconductor device 10.

(1-2) The planar size of a typical interposer is larger than the planar size of semiconductor chips so that the interposer entirely supports the semiconductor chips. Hence, the interposer is likely to bend. The bending of the interposer may produce a connection defect between the interposer and the semiconductor chip. This decreases the yield of the semiconductor device.

In this regard, in the semiconductor device 10 of the first embodiment, the connection substrate 50 is mounted on the upper surfaces of the two semiconductor chips 30. With this structure, the connection substrate 50 does not need to support the two semiconductor chips 30 and thus may have a smaller planar size than the two semiconductor chips 30. This appropriately limits bending of the connection substrate 50. Therefore, the yield of the semiconductor device 10 is improved.

(1-3) In a typical semiconductor device, three or more semiconductor chips may be mounted on the upper surface of the interposer. In this case, the area of the wiring portions of the interposer is further increased. Also, the planar size of the interposer is further increased. Therefore, the yield decreases more prominently.

In this regard, with the mount mode of the connection substrate 50 in the first embodiment, even when three or more semiconductor chips 30 are mounted on the upper surface of the wiring substrate 20, a decrease in the yield is appropriately limited.

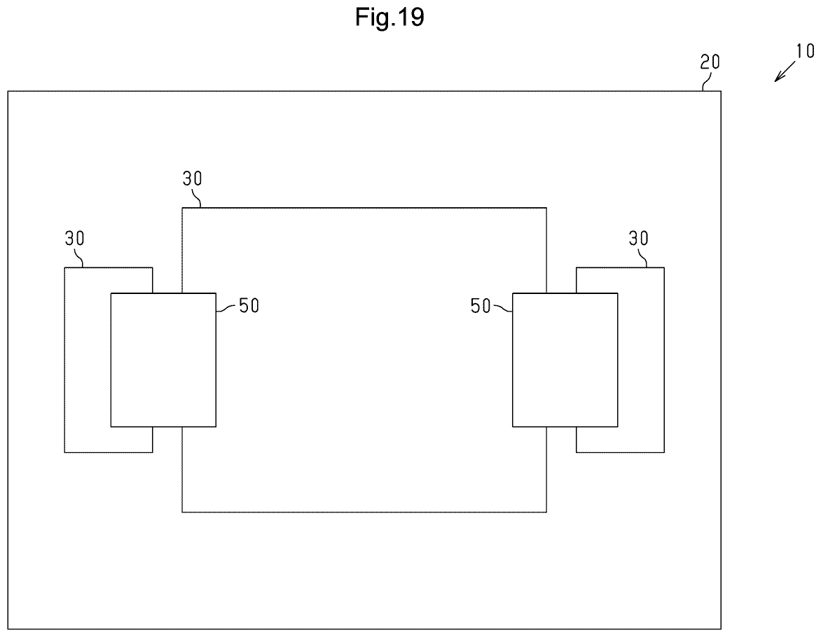

FIG. 19 illustrates an example of a semiconductor device 10 in which three semiconductor chips 30 are mounted on the upper surface of the wiring substrate 20, and two connection substrates 50 are mounted on the upper surfaces of the three semiconductor chips 30. Each of the two connection substrates 50 electrically connects only two semiconductor chips 30 located adjacent to each other among the three semiconductor chips 30. As described above, when the number of semiconductor chips 30 is increased, the number of connection substrates 50 may be increased. This limits an increase in the area of the wiring portions of the connection substrate 50 and an increase in the planar size of each connection substrate 50. With this structure, even when the number of semiconductor chips 30 mounted on the wiring substrate 20 is increased, the yield of the connection substrate 50 is improved. Accordingly, the yield of the semiconductor device 10 is improved.

(1-4) The connection substrate 50 includes the insulation layer 61 having a greater thickness than the insulation layers 72, 74, and 76 of the first wiring structural body 70. Therefore, the rigidity of the connection substrate 50 is increased as compared to a structure that does not include the insulation layer 61. This appropriately limits bending of the connection substrate 50.

(1-5) The underfill resin 41 fills the gap between the connection substrate 50 and each of the two semiconductor chips 30 and the first gap S1 between the two semiconductor chips 30. Therefore, the underfill resin 41 appropriately encapsulates the connection portions between the connection substrate 50 and the semiconductor chips 30. The underfill resin 41 also fills the first gap S1. Therefore, the underfill resin 41 appropriately protects portions of the two semiconductor chips 30.

(1-6) The planar size of the connection substrate 50 is smaller than the planar size of each of the two semiconductor chips 30. This further appropriately limits bending of the connection substrate 50.

### Second Embodiment

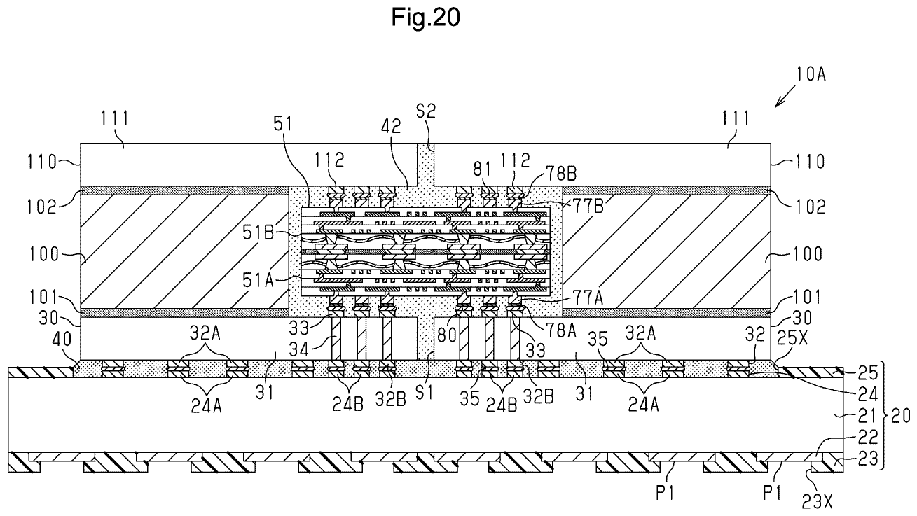

A second embodiment will now be described with reference to FIGS. 20 to 30. The differences from the first embodiment will be mainly discussed. The same reference numerals are given to those components that are the same as the corresponding components illustrated in FIGS. 1 to 19. Such components will not be described in detail.

### Structure of Semiconductor Device 10A

As illustrated in FIG. 20, a semiconductor device 10A includes a wiring substrate 20, multiple (two in the second embodiment) semiconductor chips 30 mounted on an upper surface of the wiring substrate 20, and a connection substrate 51 mounted on the upper surface of the semiconductor chips 30. The semiconductor device 10A includes one or more (two in the second embodiment) spacers 100 mounted on the upper surfaces of the semiconductor chips 30 and one or more (two in the second embodiment) semiconductor chips 110 mounted on the upper surface of the connection substrate 51 and the upper surfaces of the spacers 100. The semiconductor device 10A includes the underfill resins 40 and 42. The two semiconductor chips 110 are spaced apart by a given second gap S2 and arranged next to each other in the sideward direction of the drawing. In other words, the second gap S2 is located between the two semiconductor chips 110.

### Structure of the Connection Substrate 51

The connection substrate 51, for example, electrically connects the two semiconductor chips 30 to each other. The connection substrate 51 extends over the first gap S1 located between the two semiconductor chips 30 and is mounted on the upper surfaces of the semiconductor chips 30. The connection substrate 51, for example, electrically connects the two semiconductor chips 110 to each other. The connection substrate 51 extends over the second gap S2 located between the two semiconductor chips 110 and is mounted on the lower surfaces of the semiconductor chips 110. The connection substrate 51, for example, electrically connects the semiconductor chips 30 and the semiconductor chips 110.

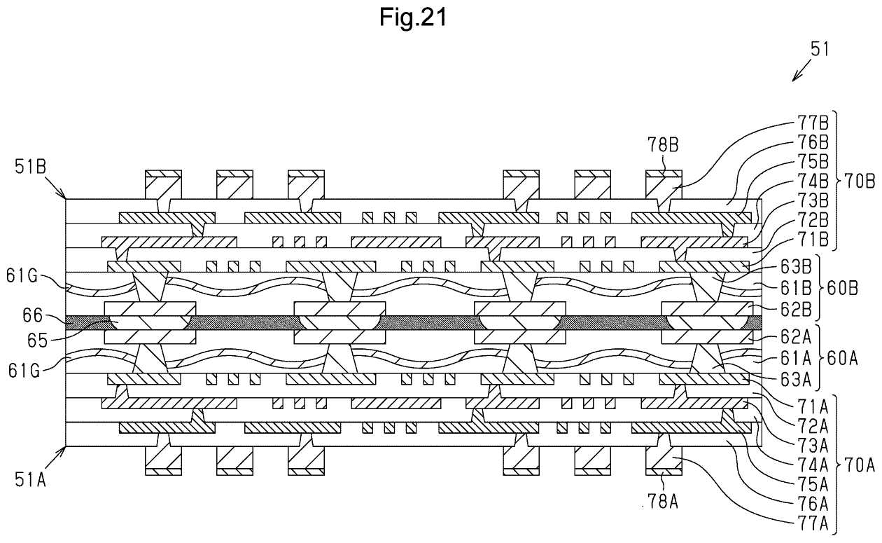

As illustrated in FIG. 21, the connection substrate 51 includes a first connection substrate 51A, a second connection substrate 51B mounted on the upper surface of the first connection substrate 51A, bonding members 65, and an underfill resin 66. The first connection substrate 51A partially has the same structure as the connection substrate 50 (refer to FIG. 2) of the first embodiment. Therefore, elements of the first connection substrate 51A, having the same structure as those of the connection substrate 50, are provided with the reference characters of the corresponding elements of the connection substrate 50 ending with “A.” Such elements will not be described in detail. The second connection substrate 51B has, for example, the same layer structure as that of the first connection substrate 51A obtained when rotated 180 degrees. Therefore, elements of the second connection substrate 51B having the same structure as those of the first connection substrate 51A are provided with the reference characters of the corresponding elements of the first connection substrate 51A ending with “B” in lieu of “A.” Such elements will not be described in detail.

### Structure of the First Connection Substrate 51A

The first connection substrate 51A includes a first structural body 60A and a first wiring structural body 70A stacked on the lower surface of the first structural body 60A. The first structural body 60A includes a wiring layer 62A, an insulation layer 61A, and a wiring layer 63A. The first wiring structural body 70A has a higher wiring density than the first structural body 60A. The first wiring structural body 70A includes a wiring layer 71A, an insulation layer 72A, a wiring layer 73A, an insulation layer 74A, a wiring layer 75A, an insulation layer 76A, and a wiring layer 77A.

### Structure of the First Structural Body 60A

The wiring layer 62A is the uppermost wiring layer of the first structural body 60A and also is the uppermost wiring layer of the first connection substrate 51A. The upper surface of the wiring layer 62A is exposed from the upper surface of the insulation layer 61A. The upper surface of the wiring layer 62A is, for example, flush with the upper surface of the insulation layer 61A. The wiring layer 62A serves as, for example, a connection terminal used for electrical connection with another substrate, namely, the second connection substrate 51B. The material of the wiring layer 62A may be, for example, copper or a copper alloy. The thickness of the wiring layer 62A may be, for example, approximately 10 μm to 30 μm. The line/space (L/S) of the wiring layer 62A may be, for example, approximately 10 μm/10 μm to 50 μm/50 μm.

The insulation layer 61A covers the lower and side surfaces of the wiring layer 62A and exposes the upper surface of the wiring layer 62A. The insulation layer 61A is the uppermost insulation layer of the first connection substrate 51A.

The wiring layer 63A is via wiring embedded in the insulation layer 61A. For example, a through hole extends through the insulation layer 61A in the thickness direction and exposes part of the lower surface of the wiring layer 62A, and the through hole is filled with via wiring defining the wiring layer 63A. The wiring layer 63A is electrically connected to the wiring layer 62A. The wiring layer 63A is the lowermost wiring layer of the first structural body 60A.

The wiring layer 63A is tapered to have a diameter that decreases from the lower side (close to the first wiring structural body 70A) toward the upper side (close to the wiring layer 62A) in FIG. 21. The wiring layer 63A has the form of, for example, a truncated cone so that its lower end surface has a larger diameter than its upper end surface. The lower end surface of the wiring layer 63A is exposed from the lower surface of the insulation layer 61A. The lower end surface of the wiring layer 63A is, for example, flush with the lower surface of the insulation layer 61A. The lower end surface of the wiring layer 63A and the lower surface of the insulation layer 61A include, for example, a polished surface. The material of the wiring layer 63A may be, for example, copper or a copper alloy.

### Structure of the First Wiring Structural Body 70A

The first wiring structural body 70A has a structure in which the wiring layer 71A, the insulation layer 72A, the wiring layer 73A, the insulation layer 74A, the wiring layer 75A, the insulation layer 76A, and the wiring layer 77A are sequentially stacked on the lower surface of the insulation layer 61A and the lower end surface of the wiring layer 63A.

Each of the wiring layers 71A, 73A, 75A, and 77A of the first wiring structural body 70A has a smaller thickness than the wiring layer 62A of the first structural body 60A. The wiring layers 71A, 73A, 75A, and 77A have a higher wiring density than the wiring layer 62A, that is, have a smaller line/space (L/S) than the wiring layer 62A.

The wiring layer 71A is formed on the lower surface of the insulation layer 61A so as to be connected to the lower end surface of the wiring layer 63A. The wiring layer 71A and the wiring layer 63A are electrically connected to each other but are not integrated with each other.

The wiring layer 77A, which is the lowermost layer of the first wiring structural body 70A, projects downward from the lower surface of the insulation layer 76A. In an example, the surface-processed layer 78A is formed on the lower surface of the wiring layer 77A. The wiring layer 77A serves as electronic component mounting pads for electrical connection with an electronic component, such as the semiconductor chips 30 (refer to FIG. 20)

### Structure of the Second Connection Substrate 51B

The second connection substrate 51B includes a second structural body 60B and a second wiring structural body 70B formed on the upper surface of the second structural body 60B. The second structural body 60B includes a wiring layer 62B, an insulation layer 61B, and a wiring layer 63B. The second wiring structural body 70B has a higher wiring density than the second structural body 60B. The second wiring structural body 70B includes a wiring layer 71B, an insulation layer 72B, a wiring layer 73B, an insulation layer 74B, a wiring layer 75B, an insulation layer 76B, and a wiring layer 77B.

### Structure of the Second Structural Body 60B

The wiring layer 62B is the lowermost wiring layer of the second structural body 60B and also is the lowermost wiring layer of the second connection substrate 51B. The wiring layer 62B serves as, for example, a connection terminal used for electrical connection with another substrate, namely, the first connection substrate 51A. The wiring layer 62B is, for example, faced to the wiring layer 62A of the first connection substrate 51A.

The insulation layer 61B covers the upper surface and side surfaces of the wiring layer 62B and exposes the lower surface of the wiring layer 62B. The insulation layer 61B is the lowermost insulation layer of the second connection substrate 51B. The insulation layer 61B has a greater thickness than each of the insulation layers 72B, 74B, and 76B of the second wiring structural body 70B. The insulation layer 61B has a greater rigidity than the insulation layers 72B, 74B, and 76B. The thickness of the insulation layer 61B may be, for example, approximately 30 μm to 80 μm.

The wiring layer 63B is via wiring embedded in the insulation layer 61B. For example, a through hole extends through the insulation layer 61B in the thickness direction and exposes part of the upper surface of the wiring layer 62B, and the through hole is filled with via wiring defining the wiring layer 63B. The wiring layer 63B is electrically connected to the wiring layer 62B. The wiring layer 63B is the uppermost wiring layer of the second structural body 60B.

The wiring layer 63B is tapered to have a diameter that decreases from the upper side (close to the second wiring structural body 70B) toward the lower side (close to the wiring layer 62B) in FIG. 21. The wiring layer 63B has the form of, for example, a reversed truncated cone so that its upper end surface has a larger diameter than its lower end surface. The upper end surface of the wiring layer 63B is exposed from the upper surface of the insulation layer 61B. The upper end surface of the wiring layer 63B is, for example, flush with the upper surface of the insulation layer 61B. The upper end surface of the wiring layer 63B and the upper surface of the insulation layer 61B include, for example, a polished surface.

### Structure of the Second Wiring Structural Body 70B

The second wiring structural body 70B has a structure in which the wiring layer 71B, the insulation layer 72B, the wiring layer 73B, the insulation layer 74B, the wiring layer 75B, the insulation layer 76B, and the wiring layer 77B are sequentially stacked on the upper surface of the insulation layer 61B and the upper end surface of the wiring layer 63B.

Each of the wiring layers 71B, 73B, 75B, and 77B of the second wiring structural body 70B has a smaller thickness than the wiring layer 62B of the second structural body 60B. The wiring layers 71B, 73B, 75B, and 77B have a higher wiring density than the wiring layer 62B, that is, have a smaller line/space (L/S) than the wiring layer 62B.

The wiring layer 71B is formed on the upper surface of the insulation layer 61B so as to be connected to the upper end surface of the wiring layer 63B. The wiring layer 71B and the wiring layer 63B are electrically connected to each other but are not integrated with each other.

The wiring layer 77B, which is the uppermost wiring layer of the second wiring structural body 70B, projects upward from the upper surface of the insulation layer 76B. In an example, the surface-processed layer 78B is formed on the upper surface of the wiring layer 77B. The wiring layer 77B serves as electronic component mounting pads for electrical connection with an electronic component, such as the semiconductor chips 110 (refer to FIG. 20).

The second connection substrate 51B is mounted on the upper surface of the first connection substrate 51A when the lower surface of the insulation layer 61B is faced to the upper surface of the insulation layer 61A. For example, the wiring layer 62B of the second connection substrate 51B is electrically connected to the wiring layer 62A of the first connection substrate 51A by the bonding members 65. The bonding members 65 are bonded to the upper surface of the wiring layer 62A and the lower surface of the wiring layer 62B.

The wiring layers 62A, 62B, 63A, 63B, 71A, 71B, 73A, 73B, 75A, 75B, 77A, and 77B serve as wiring portions configured to connect the two semiconductor chips 30 (refer to FIG. 20) or wiring portions configured to connect the two semiconductor chips 110 (refer to FIG. 20). In addition, for example, the wiring layers 62A, 62B, 63A, 63B, 71A, 71B, 73A, 73B, 75A, 75B, 77A, and 77B serve as wiring portions configured to connect the semiconductor chips 30 and the semiconductor chips 110.

The bonding members 65 may be, for example, a solder layer. The material of the solder layer may be, for example, Pb-free solder of Sn—Ag, Sn—Cu, or Sn—Ag—Cu.

The underfill resin 66 fills a gap between the first connection substrate 51A and the second connection substrate 51B. The underfill resin 66 fills a gap between the upper surface of the insulation layer 61A and the lower surface of the insulation layer 61B. The underfill resin 66 encapsulates the wiring layers 62A and 62B and the bonding members 65. The material of the underfill resin 66 may be, for example, an insulating resin such as epoxy resin.

### Structure of the Spacer 100

As illustrated in FIG. 20, the two spacers 100 are, for example, arranged on the upper surfaces of the semiconductor chips 30 in a peripheral region located at an outer side of the connection substrate 51. The two spacers 100 are, for example, arranged at opposite sides of the connection substrate 51 in the sideward direction in FIG. 20. Each spacer 100 is arranged on the upper surface of the main body 31. The lower surface of the spacer 100 is adhered to the upper surface of the main body 31 by an adhesion layer 101.

The material of the spacers 100 may be, for example, a metal material or a resin material. Preferably, the material of the spacer 100 may be, for example, the same type as the material of the main body 31 of the semiconductor chip 30. Preferably, the material of the spacer 100 may be, for example, the same type as the material of a main body 111 of the semiconductor chip 110. The spacers 100 are formed from, for example, silicon or silicon carbide.

The adhesion layers 101 and 102 may be, for example, an insulative adhesive agent including an epoxy resin or polyimide resin as a main component. The adhesion layers 101 and 102 may be, for example, a die attach film.

### Structure of the Semiconductor Chip 110

The semiconductor chip 110 includes the main body 111 and electrode pads 112 arranged on a lower portion of the semiconductor chips 110. The semiconductor chip 110 may be, for example, a logic chip or a memory chip.

The main body 111 is, for example, box-shaped. The thickness of the main body 111 may be, for example, approximately 50 μm to 200 μm. The main body 111 is formed from, for example, silicon or silicon carbide. The main body 111 has a circuit formation surface (in the embodiment, lower surface) and a back surface (upper surface) located opposite from the circuit formation surface.

The electrode pads 112, for example, project downward from the lower surface of the main body 111. The electrode pads 112 are, for example, faced to the wiring layer 77B of the connection substrate 51. The thickness of the electrode pads 112 may be, for example, approximately 2 μm to 20 μm. The material of the electrode pad 112 may be, for example, a metal such as aluminum (Al) or copper or an alloy including at least one selected from a group consisting of these metals. The electrode pads 112 may be embedded in the main body 111.

Each semiconductor chip 110 extends over the connection substrate 51 and the spacer 100 and is mounted on the upper surface of the connection substrate 51 and the upper surface of the spacer 100. The lower surface of the main body 111 of the semiconductor chip 110 is adhered to the upper surface of the spacer 100 by an adhesion layer 102.

The semiconductor chip 110 is flip-chip-mounted on the connection substrate 51 when the circuit formation surface (i.e., the lower surface of the main body 111) is faced to the upper surface of the connection substrate 51 (i.e., in face-down state). In an example, the electrode pads 112 of each semiconductor chip 110 are electrically connected to the wiring layer 77B of the connection substrate 51 (i.e., the surface-processed layer 78B formed on the upper surface of the wiring layer 77B) by bonding members 81.

The bonding members 81 may be, for example, a solder layer. The material of the solder layer may be, for example, Pb-free solder of Sn—Ag, Sn—Cu, or Sn—Ag—Cu.

### Structure of the Underfill Resin 42

The underfill resin 42 fills a gap between the connection substrate 51 and the semiconductor chips 30. The underfill resin 42 encapsulates the electrode pads 33, the wiring layer 77A, the surface-processed layer 78A, and the bonding members 80. The underfill resin 42 fills the gap between the connection substrate 51 and the semiconductor chips 110. The underfill resin 42 encapsulates the electrode pads 112, the wiring layer 77B, the surface-processed layer 78B, and the bonding members 81. The underfill resin 42 fills, for example, the first gap S1 between the two semiconductor chips 30. The underfill resin 42 fills, for example, the second gap S2 between the two semiconductor chips 110. The underfill resin 42 fills, for example, the gap between the connection substrate 51 and the spacer 100. The material of the underfill resin 42 may be, for example, an insulating resin such as epoxy resin.

### Method for Manufacturing the Connection Substrate 51

A method for manufacturing the connection substrate 51 will now be described. Of the first connection substrate 51A and the second connection substrate 51B, a method for manufacturing the first connection substrate 51A will now be described. The second connection substrate 51B may be manufactured in the same method as the first connection substrate 51A and thus will not be described in detail. To facilitate understanding, parts that ultimately become elements of the connection substrate 51 are indicated by reference characters used to denote the final elements.

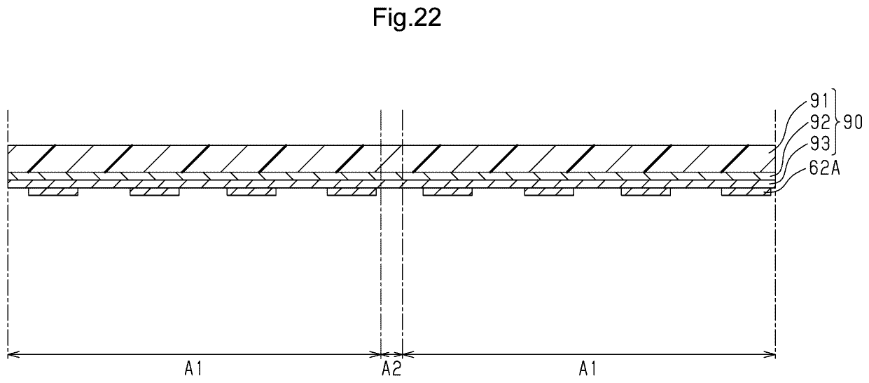

As illustrated in FIG. 22, in the same manner as the step illustrated in FIG. 4, a large support 90 including multiple separate regions Al is prepared. The wiring layer 62A is formed on the lower surface of the metal film 93 of the support 90. The wiring layer 62A may be formed, for example, through any of various wiring formation processes such as a semi-additive process.

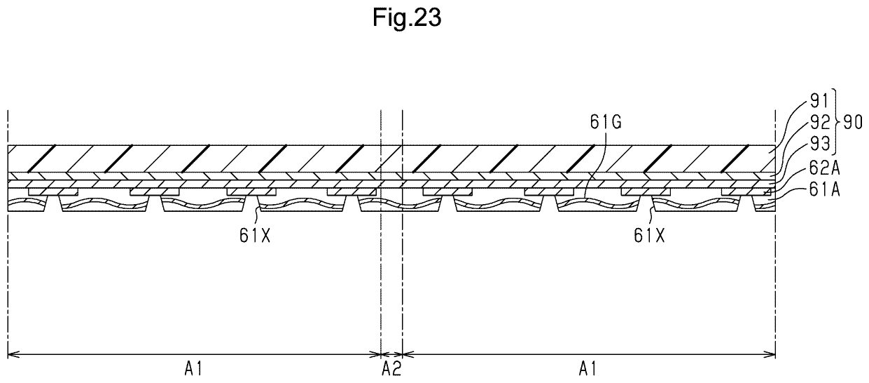

In the step illustrated in FIG. 23, the insulation layer 61A is formed on the lower surface of the metal film 93 and covers the wiring layer 62A in a manner similar to the step of FIG. 5. Subsequently, through holes 61X are formed in given locations of the insulation layer 61A to expose part of the lower surface of the wiring layer 62A. The through holes 61X may be formed by, for example, laser drilling using CO₂ laser, UV-YAG laser, or the like.

When the through holes 61X are formed by laser cutting, a desmear process is performed to remove resin smears from the surface of the wiring layer 62A exposed at the bottom of each through hole 61X.

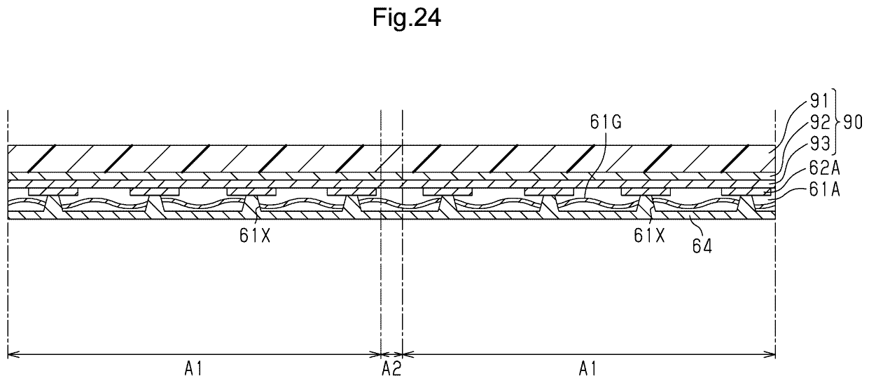

In the step illustrated in FIG. 24, a conductive layer 64 is formed by electrolytic plating (in this embodiment, electrolytic Cu plating) to fill the through holes 61X and cover the entire lower surface of the insulation layer 61A.

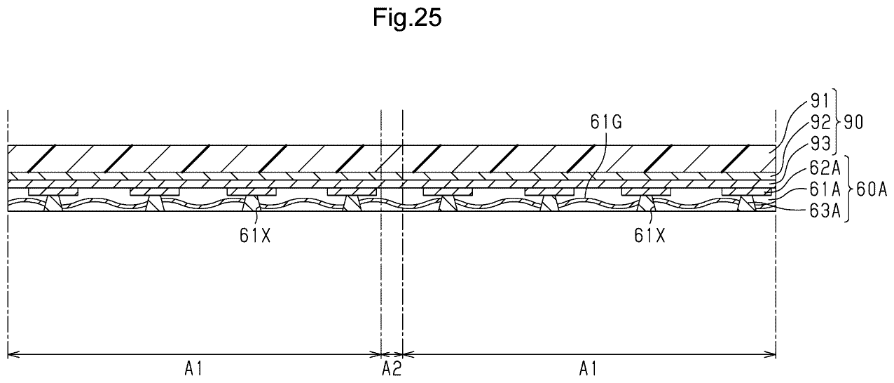

In the step illustrated in FIG. 25, for example, CMP is performed to polish the conductive layer 64 (refer to FIG. 24) projecting from the lower surface of the insulation layer 61A and part of the lower surface of the insulation layer 61A. Consequently, the wiring layer 63A, which fills the through holes 61X, is formed. The lower end surface of the wiring layer 63A is flush with the lower surface of the insulation layer 61A. As a result of the polishing in this step, the lower end surface of the wiring layer 63A and the lower surface of the insulation layer 61A each include a polished surface.

Through the manufacturing process described above, the structural body corresponding to the first structural body 60A is formed in each of the separate regions Al.

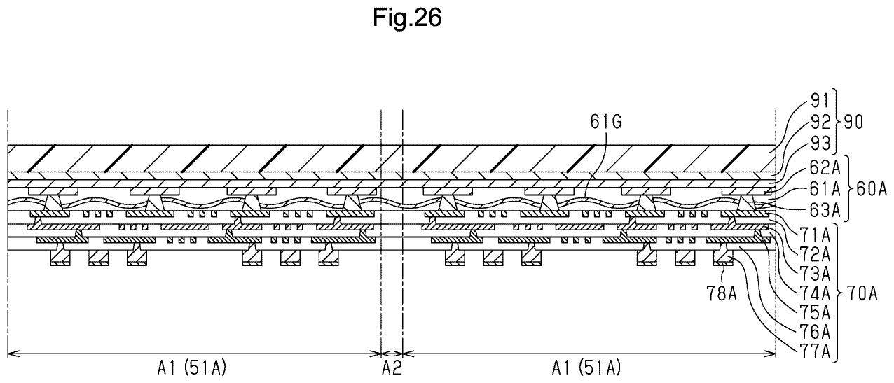

In the step illustrated in FIG. 26, the wiring layer 71A is formed on the lower end surface of the wiring layer 63A and the lower surface of the insulation layer 61A. The wiring layer 71A may be formed, for example, through any of various wiring formation processes such as a semi-additive process. Subsequently, the insulation layer 72A, the wiring layer 73A, the insulation layer 74A, the wiring layer 75A, the insulation layer 76A, and the wiring layer 77A are sequentially stacked on the lower surface of the insulation layer 61A in a manner similar to the steps of FIGS. 7 to 10. Subsequently, the surface-processed layer 78A is formed on the lower surface of the wiring layer 77A in a manner similar to the step of FIG. 11.

The manufacturing steps described above form the first wiring structural body 70A on the lower surface of the first structural body 60A. A structure corresponding to the first connection substrate 51A is manufactured in each separate region A1.

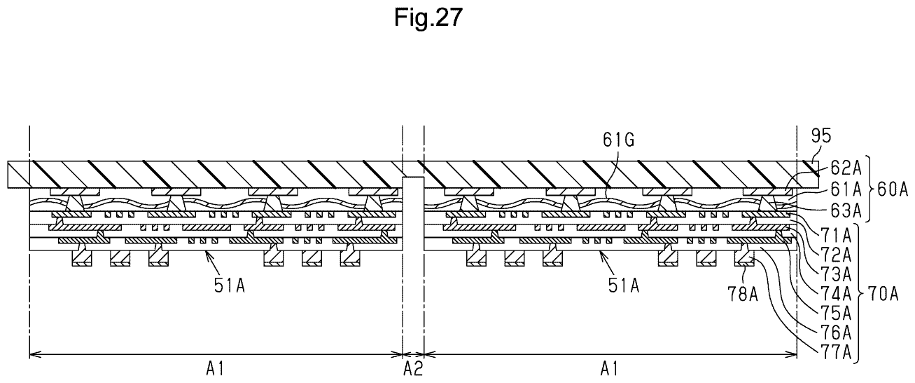

In the step illustrated in FIG. 27, subsequent to removal of the support 90 illustrated in FIG. 26, the tape 95 is adhered to the upper surface of the insulation layer 61A and the upper surface of the wiring layer 62A in a manner similar to the steps of FIGS. 12 to 14. The structural body to which the tape 95 is attached is cut using a dicing blade along the cutting region A2. This singulates the first connection substrates 51A, thereby manufacturing multiple first connection substrates 51A. The first connection substrate 51A is mechanically separated from the tape 95.

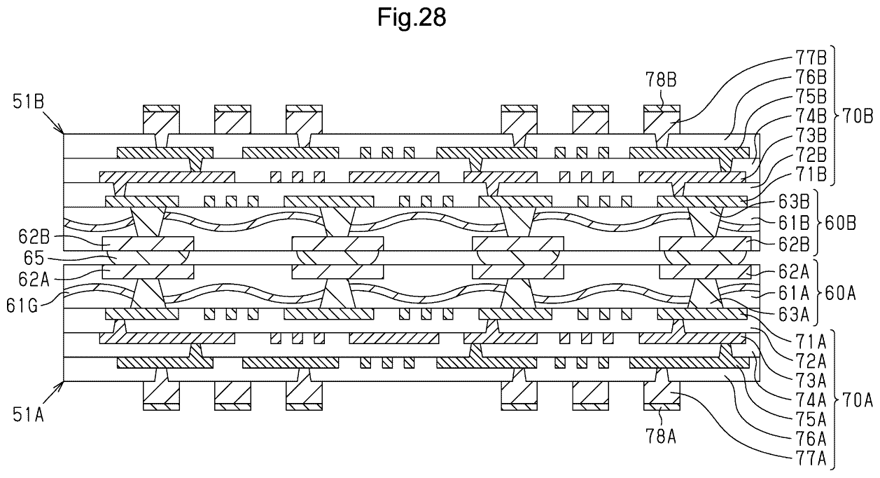

In the step illustrated in FIG. 28, the first connection substrate 51A, which is manufactured through the steps illustrated in FIGS. 22 to 27, is prepared. Also, the second connection substrate 51B, which is manufactured in a manner similar to the first connection substrate 51A, is prepared. The second connection substrate 51B is arranged above the first connection substrate 51A. In this step, the second connection substrate 51B is configured to face the wiring layer 62B and the insulation layer 61B to the first connection substrate 51A. The first connection substrate 51A and the second connection substrate 51B are positioned so that the wiring layer 62A of the first connection substrate 51A is vertically aligned with the wiring layer 62B of the second connection substrate 51B.

The second connection substrate 51B is mounted on the upper surface of the first connection substrate 51A. For example, the wiring layer 62B of the second connection substrate 51B is bonded to the wiring layer 62A of the first connection substrate 51A by the bonding members 65. As illustrated in FIG. 21, the underfill resin 66 fills the gap between the first connection substrate 51 A and the second connection substrate 51B. Then, the underfill resin 66 is cured. Alternatively, the underfill resin 66 may be applied to the lower surface of the second connection substrate 51B in advance. Then, when the second connection substrate 51B is mounted, the underfill resin 66 may fill the gap to the upper surface of the first connection substrate 51A. The manufacturing steps described above manufacture the connection substrate 51 of the second embodiment.

### Method for Manufacturing the Semiconductor Device 10A

A method for manufacturing the semiconductor device 10A will now be described. To facilitate understanding, parts that ultimately become elements of the semiconductor device 10A are indicated by reference characters used to denote the final elements.

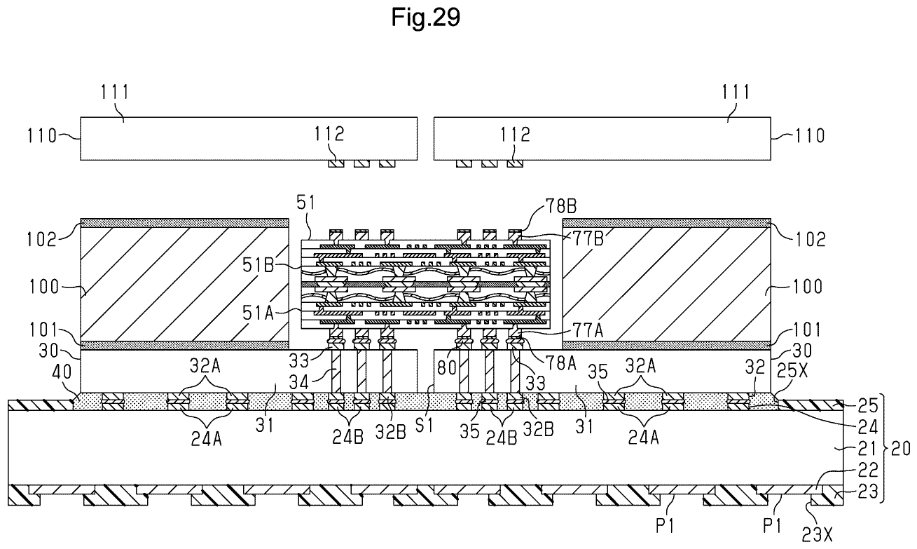

In the step illustrated in FIG. 29, the two semiconductor chips 30 are mounted on the wiring substrate 20, and the connection substrate 51 is mounted on the two semiconductor chips 30 in a manner similar to the steps of FIGS. 17 and 18.

The spacers 100 are fixed to the upper surface of the semiconductor chips 30. In an example, the spacers 100 are adhered to the upper surface of the semiconductor chips 30 by the adhesion layer 101.

In the step illustrated in FIG. 29, the two semiconductor chips 110 including the main body 111 and the electrode pads 112 are arranged above the connection substrate 51. In this state, each semiconductor chip 110 is arranged to extend over the connection substrate 51 and the spacer 100. The semiconductor chips 110 and the connection substrate 51 are positioned so that the electrode pads 112 of the semiconductor chips 110 are vertically aligned with the wiring layer 77B of the connection substrate 51.

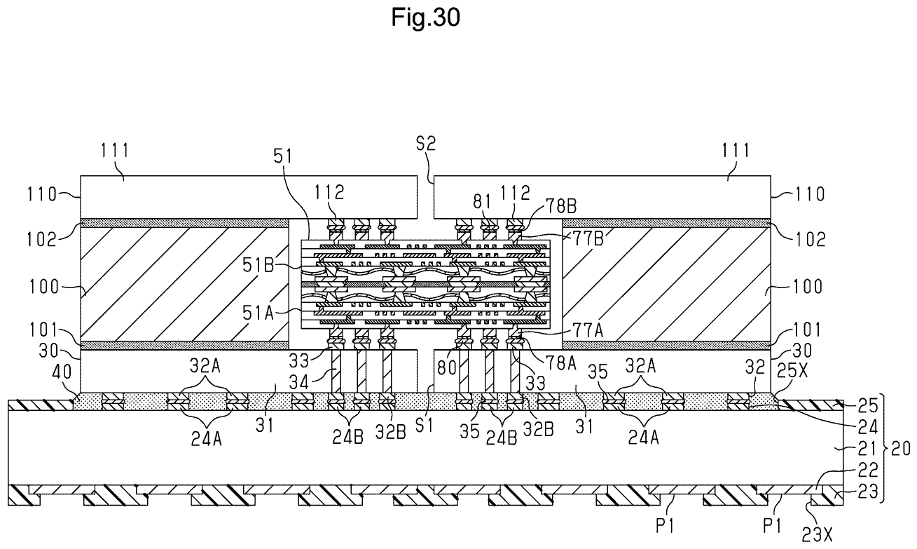

In the step illustrated in FIG. 30, the two semiconductor chips 110 are mounted on the connection substrate 51, and the semiconductor chips 110 are fixed to the spacers 100. The two semiconductor chips 110 are spaced apart by the given second gap S2 and arranged next to each other on the connection substrate 51 in the sideward direction of the drawing. Each semiconductor chip 110 is face down and is flip-chip-mounted on the connection substrate 51. In an example, the electrode pads 112 of the semiconductor chips 110 are bonded to the wiring layer 77B of the connection substrate 51 by the bonding members 81. In addition, the semiconductor chips 110 are bonded to the upper surfaces of the spacers 100 by the adhesion layer 102.

As illustrated in FIG. 20, the underfill resin 42 fills the gap between the connection substrate 51 and the semiconductor chips 30, the gap between the connection substrate 51 and the semiconductor chips 110, and the gap between the connection substrate 51 and the spacers 100. Then, the underfill resin 42 is cured. In the second embodiment, the underfill resin 42 fills the first gap S1 between the two semiconductor chips 30 and the second gap S2 between the semiconductor chips 110. The semiconductor device 10A of the second embodiment is manufactured through the manufacturing steps described above.

In the second embodiment, the semiconductor chip 30 is an example of a first electronic component. The electrode pad 32 is an example of a first electrode pad. The electrode pad 33 is an example of a second electrode pad. The insulation layer 61A is an example of a first insulation layer. The wiring layer 62A is an example of a second wiring layer. The wiring layer 63A is an example of a third wiring layer. The wiring layers 71A, 73A, 75A, and 77A are each an example of a first wiring layer. The insulation layers 72A, 74A, and 76A are each an example of a second insulation layer. The insulation layer 61B is an example of a third insulation layer. The wiring layer 62B is an example of a fourth wiring layer. The wiring layer 63B is an example of a fifth wiring layer. The wiring layers 71B, 73B, 75B, and 77B are each an example of a sixth wiring layer. The insulation layers 72B, 74B, and 76B are each an example of a fourth insulation layer. The semiconductor chip 110 is an example of a second electronic component. The electrode pad 112 is an example of a third electrode pad. The underfill resin 40 is an example of a second underfill resin. The underfill resin 42 is an example of a first underfill resin.

### Advantages of the Second Embodiment

The second embodiment may have the advantages described below in addition to the advantages (1-1) to (1-6) of the first embodiment.

(2-1) The connection substrate 51 has a structure in which the second connection substrate 51B having the uppermost wiring layer 77B is mounted on the upper surface of the first connection substrate 51A having the lowermost wiring layer 77A. Thus, the semiconductor chips 30 and 110 are mounted on both the upper and lower surfaces of the connection substrate 51.

(2-2) The spacers 100 are arranged on the upper surfaces of the semiconductor chips 30. In addition, the semiconductor chips 110 are mounted on the upper surfaces of the spacers 100 and the upper surface of the connection substrate 51. With this structure, the spacers 100 support the semiconductor chips 110. Thus, the semiconductor chips 110 are stably mounted on the upper surfaces of the spacers 100 and the upper surface of the connection substrate 51.

(2-3) The spacers 100 are formed from the same type of material as the main body 31 of the semiconductor chips 30. Thus, thermal expansion coefficients of the spacers 100 and the main body 31 are substantially equal. This appropriately limits bending of the semiconductor device 10.

### Modified Examples

The embodiments described above may be modified as follows. The embodiments and the following modified examples may be combined as long as the combined modified examples remain technically consistent with each other.

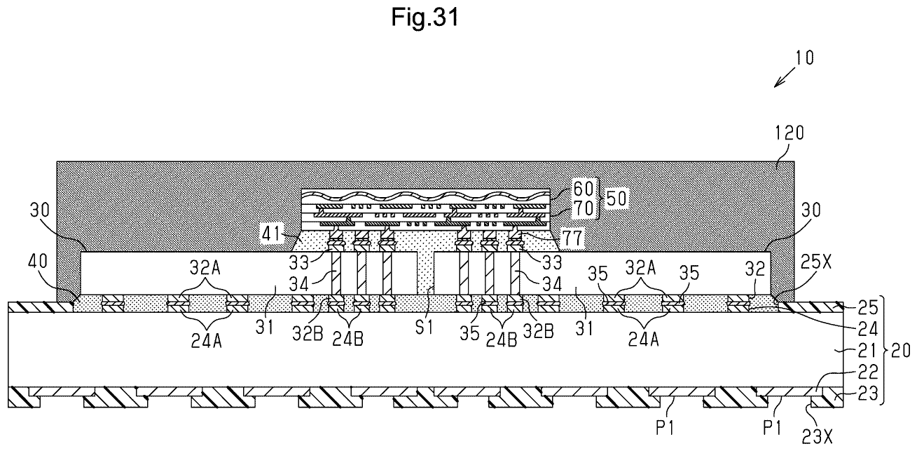

As illustrated in FIG. 31, the semiconductor chips 30 and the connection substrate 50 may be encapsulated by an encapsulation resin 120. The encapsulation resin 120 is, for example, formed on the upper surface of the wiring substrate 20. The encapsulation resin 120 is, for example, formed on the upper surface of the solder resist layer 25. The encapsulation resin 120 covers, for example, the entire surface of the semiconductor chips 30 exposed from the underfill resins 40 and 41. The encapsulation resin 120 covers the entire surface of the connection substrate 50 exposed from the underfill resins 40 and 41. The encapsulation resin 120 covers, for example, the entire surface of the underfill resins 40 and 41.

The material of the encapsulation resin 120 may be, for example, a non-photosensitive insulating resin containing a thermosetting resin as a main component. The material of the encapsulation resin 120 may be, for example, an insulative resin, such as epoxy resin and polyimide resin, or a resin material obtained by mixing the resin with a filler such as silica and alumina. The encapsulation resin 120 may be, for example, a mold resin.

With this structure, the semiconductor chips 30 and the connection substrate 50 are encapsulated by the encapsulation resin 120. Thus, the semiconductor chips 30 and the connection substrate 50 are appropriately protected.

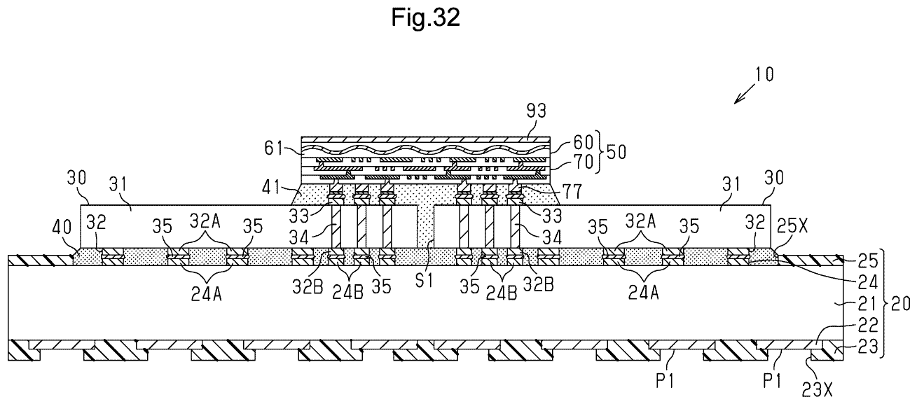

As illustrated in FIG. 32, the metal film 93 may be arranged on the upper surface of the first structural body 60 of the connection substrate 50. The metal film 93 is formed on the upper surface of the insulation layer 61. The metal film 93 covers, for example, the entire upper surface of the insulation layer 61.

With this structure, the metal film 93 is arranged on an outer surface of the connection substrate 50. This improves the heat dissipation property of the connection substrate 50. Ultimately, the heat dissipation property of the entire semiconductor device 10 is improved.

A method for manufacturing the connection substrate 50 illustrated in FIG. 32 will now be described.

First, steps similar to the steps of FIGS. 4 to 12 are performed to manufacture the structural body illustrated in FIG. 12. That is, the base 91 and the metal foil 92 of the support 90 (refer to FIG. 11) are removed to manufacture a structural body in which only the metal film 93 of the support 90 remains on the upper surface of the insulation layer 61.

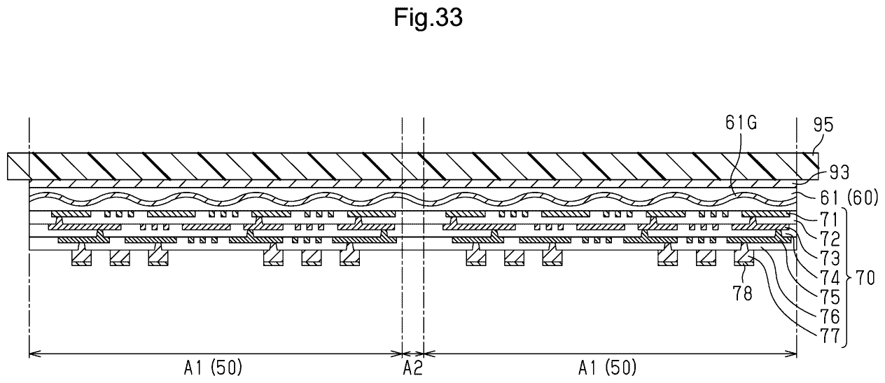

In the step illustrated in FIG. 33, the metal film 93 remains, and the tape 95 is adhered to the upper surface of the metal film 93.

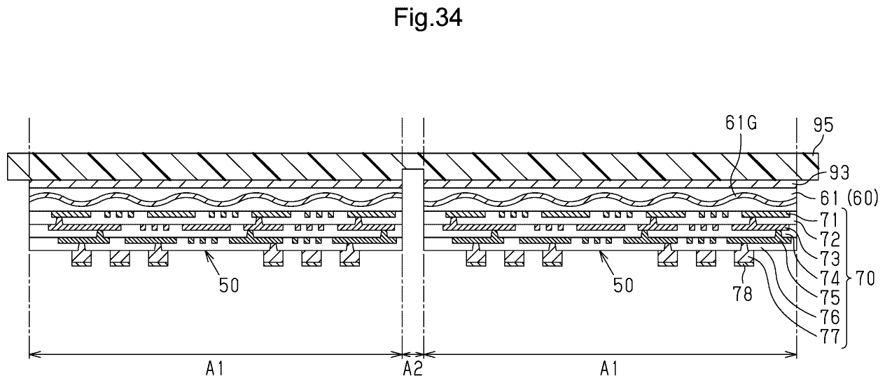

In the step illustrated in FIG. 34, the structural body to which the tape 95 is attached is cut using a dicing blade along the cutting region A2. In this modified example, the metal film 93, the insulation layer 61, and the insulation layers 72, 74, and 76 of the first wiring structural body 70 located in the cutting region A2 are cut. The connection substrate 50 is mechanically separated from the tape 95.

The manufacturing steps described above manufacture the connection substrate 50 illustrated in FIG. 32.

In the modified example illustrated in FIG. 32, a metal layer may be further arranged on the upper surface of the metal film 93.

In each embodiment described above, the number of semiconductor chips 30 mounted on the upper surface of the wiring substrate 20 is not limited. For example, as illustrated in FIG. 19, three or more semiconductor chips 30 may be mounted on the upper surface of the wiring substrate 20.

In the second embodiment, the number of semiconductor chips 110 mounted on the upper surface of the connection substrate 51 is not limited. In an example, one semiconductor chip 110 may be mounted on the upper surface of the connection substrate 51.

In the second embodiment, instead of the semiconductor chip 110, a chip component such as a chip capacitor, a chip resistor, or a chip inductor, or an electronic component other than a semiconductor chip, such as a crystal oscillator, may be mounted on the connection substrate 51.

In each embodiment described above, instead of the semiconductor chip 30, a chip component or an electronic component other than a semiconductor chip, such as a crystal oscillator, may be mounted on the wiring substrate 20.

In the second embodiment, the spacers 100 may be formed from a material differing from the material of the main body 31 of the semiconductor chip 30.

In the second embodiment, the spacers 100 may be omitted.

In the second embodiment, the underfill resin 42 is formed to fill the first gap S1. However, there is no limitation to such a structure. In an example, the underfill resin 42 may be formed without filling the first gap S1.

In the second embodiment, the underfill resin 42 is formed to fill the second gap S2. However, there is no limitation to such a structure. In an example, the underfill resin 42 may be formed without filling the second gap S2.

In the second embodiment, the underfill resin 42 is formed to fill the gap between the connection substrate 51 and the spacer 100. However, there is no limitation to such a structure. In an example, the underfill resin 42 may be formed without filling the gap between the connection substrate 51 and the spacer 100.

In the second embodiment, the gap between the semiconductor chip 30 and the connection substrate 51 and the gap between the connection substrate 51 and the semiconductor chip 110 may each be filled with a different underfill resin 42.

In the first embodiment, the two semiconductor chips 30 are provided with the common underfill resin 41. Alternatively, for example, a different underfill resin 41 may be separately provided on each of the two semiconductor chips 30.

In the first embodiment, the underfill resin 41 is formed to fill the first gap S1. However, there is no limitation to such a structure. In an example, the underfill resin 41 may be formed without filling the first gap S1.

In the embodiments described above, the two semiconductor chips 30 are provided with the common underfill resin 40. Alternatively, for example, a different underfill resin 40 may be separately provided on each of the two semiconductor chips 30.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a wiring substrate including a connection pad;
two first electronic components mounted on an upper surface of the wiring substrate; and
a connection substrate extending over the two first electronic components and mounted on upper surfaces of the two first electronic components, the connection substrate electrically connecting the two first electronic components to each other, wherein
each of the two first electronic components includes a main body, a first electrode pad arranged on a lower surface of the main body and electrically connected to the connection pad, a second electrode pad arranged on an upper surface of the main body, which is opposite from the first electrode pad, and a through electrode extending through the main body in a thickness direction and electrically connecting the first electrode pad and the second electrode pad,
the connection substrate includes a first structural body including a first insulation layer, and a first wiring structural body stacked on a lower surface of the first structural body,
the first wiring structural body has a structure in which multiple first wiring layers and multiple second insulation layers are stacked,
the first insulation layer is greater in thickness than each of the multiple second insulation layers, and
a lowermost first wiring layer of the multiple first wiring layers is electrically connected to the second electrode pad.

2. The semiconductor device according to claim 1, further comprising:
a first underfill resin filling a gap between the connection substrate and the two first electronic components,
wherein the first underfill resin encapsulates the lowermost first wiring layer and the second electrode pad.

3. The semiconductor device according to claim 2, wherein
the two first electronic components are spaced apart by a first gap and arranged next to each other, and
the first underfill resin fills the first gap.

4. The semiconductor device according to claim 1, wherein
each of the two first electronic components is a semiconductor chip,
the semiconductor chip includes a circuit formation surface faced to the upper surface of the wiring substrate and is flip-chip-mounted on the wiring substrate, and
the semiconductor device further comprises a second underfill resin that fills a gap between the circuit formation surface of the semiconductor chip and the upper surface of the wiring substrate.

5. The semiconductor device according to claim 1, wherein the first structural body has a thickness that is greater than or equal to a thickness of the first wiring structural body.

6. The semiconductor device according to claim 1, wherein the connection substrate has a thickness that is less than a thickness of each of the two first electronic components.

7. The semiconductor device according to claim 1, wherein
the first structural body includes only the first insulation layer including a reinforcement member, and
the first wiring structural body is stacked on a lower surface of the first insulation layer.

8. The semiconductor device according to claim 7, wherein the first insulation layer defines an uppermost layer of the connection substrate.

9. The semiconductor device according to claim 1, wherein
the first structural body includes the first insulation layer including a reinforcement member, and multiple wiring layers,
the first wiring structural body is stacked on a lower surface of the first insulation layer, and
the first wiring structural body has a wiring density that is higher than that of the first structural body, 10. The semiconductor device according to claim 1, further comprising:
an encapsulation resin formed on the upper surface of the wiring substrate to encapsulate the two first electronic components and the connection substrate.

11. The semiconductor device according to claim 1, wherein
the first structural body includes only the first insulation layer, and
the connection substrate includes a metal film formed on an upper surface of the first insulation layer.

12. The semiconductor device according to claim 1, further comprising:
a second electronic component mounted on an upper surface of the connection substrate and including a third electrode pad, wherein
the connection substrate includes a first connection substrate including the first structural body and the first wiring structural body, and a second connection substrate mounted on an upper surface of the first connection substrate,
the first structural body includes a second wiring layer, which is an uppermost wiring layer of the first structural body, the first insulation layer covering an uppermost first wiring layer of the multiple first wiring layers, and a third wiring layer extending through the first insulation layer in a thickness direction and including a lower end surface exposed from a lower surface of the first insulation layer, the third wiring layer being electrically connected to the second wiring layer,
the first wiring structural body is stacked on the lower surface of the first insulation layer,
the first wiring structural body has a wiring density that is higher than that of the first structural body,
the second connection substrate includes a second structural body and a second wiring structural body stacked on an upper surface of the second structural body,
the second structural body includes a fourth wiring layer, which is a lowermost wiring layer of the second structural body, a third insulation layer covering the fourth wiring layer, and a fifth wiring layer extending through the third insulation layer in a thickness direction and including an upper end surface exposed from an upper surface of the third insulation layer, the fifth wiring layer being electrically connected to the fourth wiring layer,
the second wiring structural body has a structure in which multiple sixth wiring layers and multiple fourth insulation layers are stacked on the upper surface of the third insulation layer,
the second wiring structural body has a wiring density that is higher than that of the second structural body,
the third insulation layer is greater in thickness than each of the fourth insulation layers,
the fourth wiring layer is bonded to the second wiring layer, and
an uppermost sixth wiring layer of the multiple sixth wiring layers is electrically connected to the third electrode pad.

13. The semiconductor device according to claim 12, wherein the second connection substrate has a structure in which the first connection substrate is vertically inverted.

14. The semiconductor device according to claim 12, further comprising:
a spacer arranged on the upper surfaces of the two first electronic components,
wherein the second electronic component extends over the second connection substrate and the spacer and is mounted on an upper surface of the second connection substrate and an upper surface of the spacer.

15. The semiconductor device according to claim 14, wherein the spacer and the main body are formed from a same type of material.

16. The semiconductor device according to claim 1, wherein the connection substrate is smaller in planar size than each of the two first electronic components.
